(19) United States
(12) Patent Application Publication
(10) Pub. No.: US 2026/0362784 A1
(43) Pub. Date: Nov. 12, 2026

(54) CAPPING LAYERS OF FIN STRUCTURES IN SEMICONDUCTOR DEVICES

(71) Applicant: Taiwan Semiconductor Manufacturing Company, Ltd., Hsinchu (TW)

(72) Inventors: Pradeep Balaji, Glendale, AZ (US); Chih-Lin Wang, Tempe, AZ (US); Jonathan Hartanto, Stanford, CA (US)

(73) Assignees: Taiwan Semiconductor Manufacturing Company, Ltd., Hsinchu (TW); Taiwan Arizona Corporation, Phoenix, AZ (US)

(21) Appl. No.: 19/204,335

(22) Filed: May 9, 2025

(51) Int. Cl. H10D 84/01; H10D 84/85

(52) U.S. Cl. CPC H10D 84/0167; H10D 84/017; H10D 84/0186; H10D 84/0193; H10D 84/853; H10D 84/856

(57) ABSTRACT

A semiconductor structure and a method of fabricating the structure are disclosed. The method includes epitaxially growing a first fin structure having a first material on a substrate, epitaxially growing a second fin structure having a second material on the substrate, forming a first fin capping layer on the first and second fin structures, converting a portion of the first fin capping layer into a second fin capping layer on the first fin structure, forming first and second fin barrier layers on the first and second fin capping layers, respectively, forming first and second polysilicon structures on the first and second fin barrier layers, respectively, epitaxially growing a first source/drain region on the first fin structure, epitaxially growing a second source/drain region on the second fin structure, and replacing the first and second polysilicon structures with first and second gate structures.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device with fin capping layers, in accordance with some embodiments.

FIGS. 1B-1I illustrate different cross-sectional views of a semiconductor device with fin capping layers, in accordance with some embodiments.

FIG. 2 is a flow diagram of a method for fabricating a semiconductor device with fin capping layers, in accordance with some embodiments.

FIGS. 3A-16A, 3B-16B, and 3C-16C illustrate cross-sectional views of a semiconductor device with fin capping layers at various stages of its fabrication process, in accordance with some embodiments.

FIG. 17 is a flow diagram of a method for fabricating another semiconductor device with fin capping layers, in accordance with some embodiments.

FIGS. 18-25 illustrate cross-sectional views of another semiconductor device with fin capping layers at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15~20% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The present disclosure provides example semiconductor devices with p-type FinFETs (“PFETs”) and n-type FinFETs (“NFETs”) having fin capping layers for improving device performance. The present disclosure also provides examples methods of fabricating these semiconductor devices. In some embodiments, a PFET can include p-type fin structures, p-type fin capping layers disposed along sidewalls of the p-type fin structures, and fin barrier layers disposed on the p-type fin capping layers. In some embodiments, the fin barrier layers can prevent the diffusion of atoms to and from the p-type fin structures and improve surface quality of the p-type fin structures, and the p-type fin capping layers can improve the interface between the fin barrier layers and the p-type fin structures.

In some embodiments, the p-type fin structures can include a material (e.g., silicon germanium (SiGe)) with a lattice constant that is different from the material (e.g., silicon oxide (SiO₂)) of the fin barrier layers, which can induce strain on the p-type fin structures due to lattice mismatch between the materials of the p-type fin structures and the fin barrier layers. Such strain can induce crystal defects, such as dislocations and voids in the p-type fin structures, which can degrade the performance of the PFETs (e.g., increase device threshold voltage). The p-type fin capping layers can include a material (e.g., silicon germanium oxide (SiGeOₓ)) that can reduce the strain between the p-type fin structures and the fin barrier layers, thus improving the device performance.

Similarly, in some embodiments, an NFET can include n-type fin structures, n-type fin capping layers disposed along sidewalls of the n-type fin structures, and fin barrier layers disposed on the n-type fin capping layers. In some embodiments, the n-type fin structures and the n-type fin capping layers can include the same semiconductor material (e.g., silicon (Si)) and the fin barrier layers can include the same material (e.g., SiO₂) as the barrier layers of the PFET.

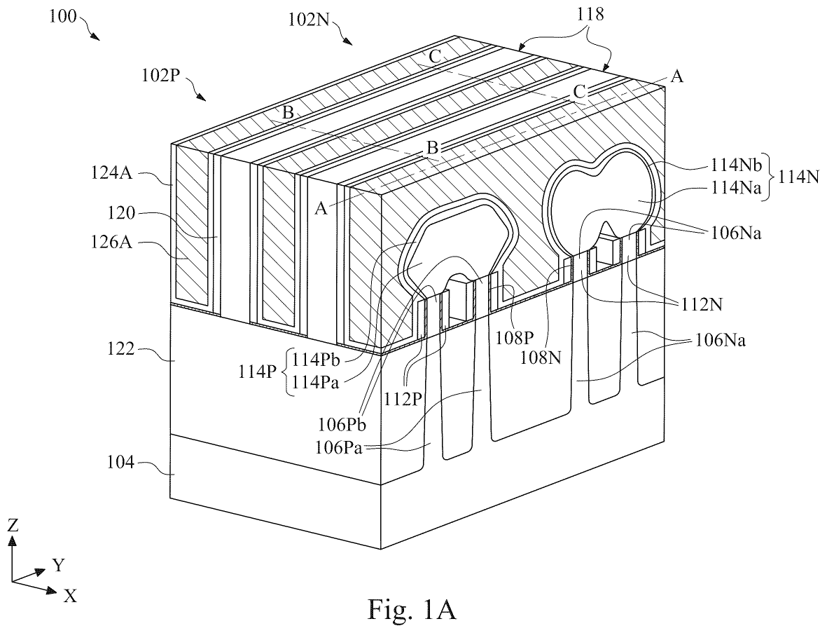

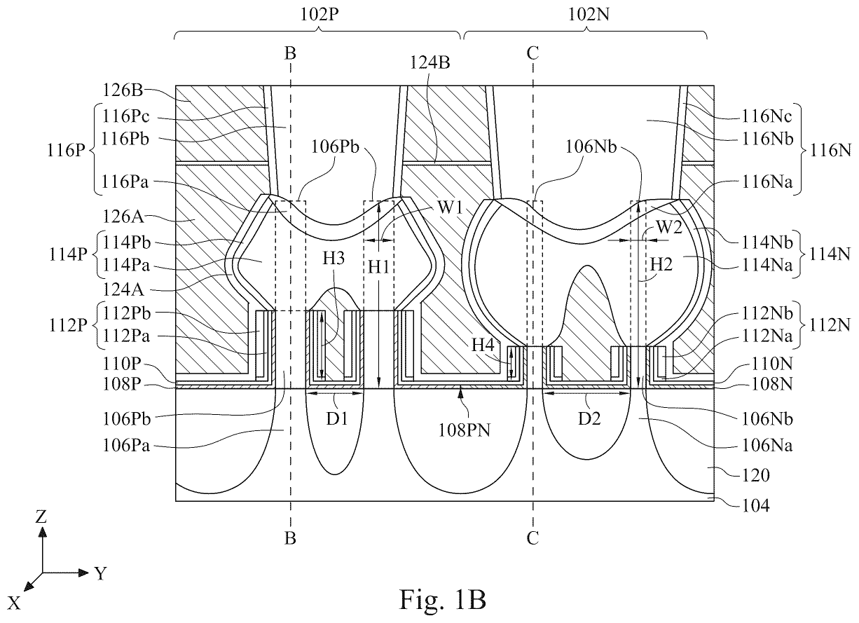

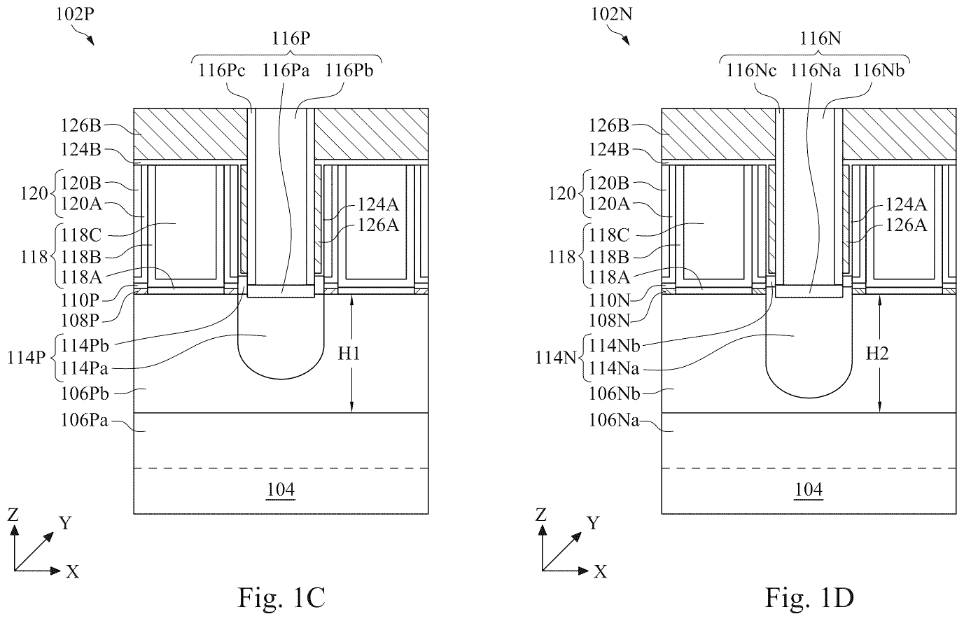

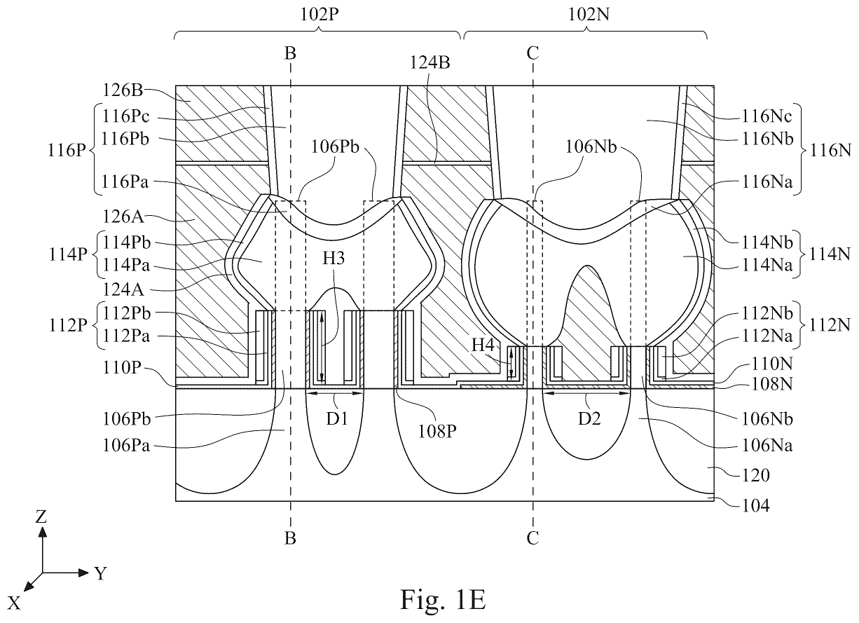

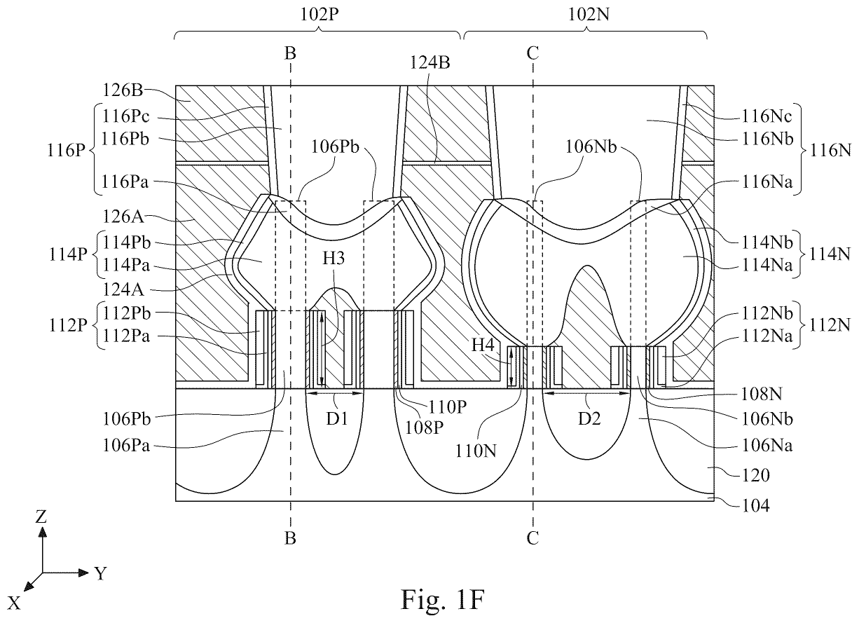

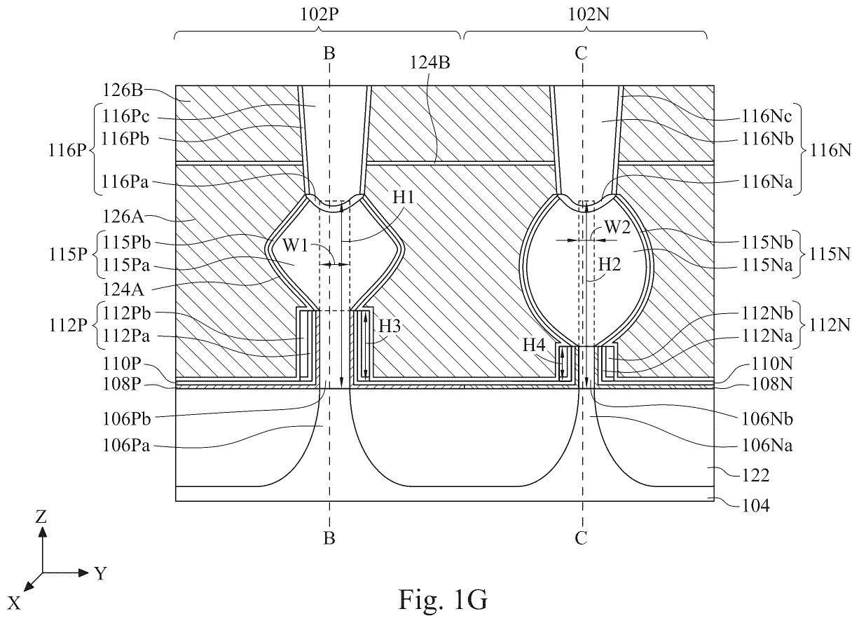

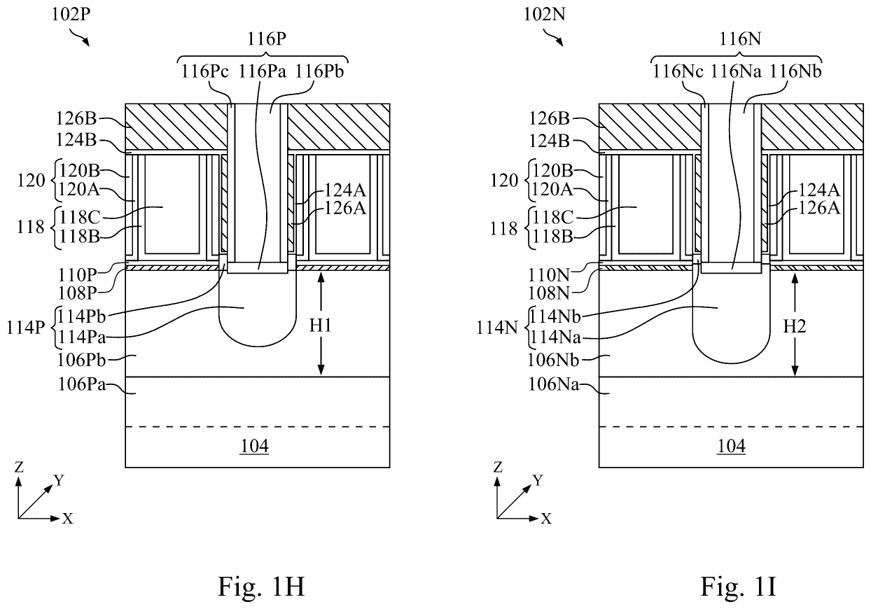

FIG. 1A illustrates an isometric view of a semiconductor device 100 with a p-type FinFET 102P (also referred to as “PFET 102P”) and an n-type FinFET 102N (also referred to as “NFET 102N”), according to some embodiments. FIGS. 1B, 1E, and 1F illustrate different cross-sectional views of semiconductor device 100 along line A-A of FIG. 1A, with additional structures that are not shown in FIG. 1A for simplicity, according to some embodiments. FIGS. 1C and 1H illustrate different cross-sectional views of semiconductor device 100 along lines B-B of FIGS. 1A, 1B, 1E, and 1F, with additional structures that are not shown in FIG. 1A for simplicity and that are not visible in FIG. 1B, according to some embodiments. FIGS. 1D and 1I illustrate different cross-sectional views of semiconductor device 100 along lines C-C of FIGS. 1A, 1B, 1E, and 1F, with additional structures that are not shown in FIG. 1A for simplicity and that are not visible in FIG. 1B, according to some embodiments. The discussion of elements in FIGS. 1A-1F and 1H-1I with the same annotations applies to each other, unless mentioned otherwise.

Referring to FIGS. 1A-1F, semiconductor device 100 can include a substrate 104 with PFET 102P and NFET 102N formed on different regions of substrate 104. In some embodiments, substrate 104 can be a semiconductor material, such as silicon (Si), germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic).

In some embodiments, PFET 102P can include (i) fin bases 106Pa, (ii) fin structures 106Pb, (iii) fin capping layers 108P, (iv) fin barrier layers 110P (also referred to as “fin passivation layers 110P”), (v) fin spacers 112P (not visible in FIGS. 1C and 1D), (vi) S/D regions 114P (not visible in FIG. 1D), and (vii) contact structures 116P (not shown in FIG. 1A for simplicity). Similarly, in some embodiments, NFET 102N can include (i) fin bases 106Na, (ii) fin structures 106Nb, (iii) fin capping layers 108N, (iv) fin barrier layers 110N (also referred to as “fin passivation layers 110N”), (v) fin spacers 112N (not visible in FIGS. 1C and 1D), (vi) S/D regions 114N (not visible in FIG. 1C), and (vii) contact structures 116N (not shown in FIG. 1A for simplicity). In some embodiments, semiconductor device 100 can further include (i) gate structures 118 (not visible in FIGS. 1B, 1E, and 1F), (ii) gate spacers 120 (not visible in FIGS. 1B, 1E, and 1F), (iii) shallow trench isolation (STI) regions 122 (not visible in FIGS. 1C and 1D), (iv) etch stop layers (ESLs) 124A and 124B (ESL 124B not shown in FIG. 1A for simplicity), and (v) interlayer dielectric (ILD) layers 126A and 126B (ILD layer 126B not shown in FIG. 1A for simplicity). In some embodiments, PFET 102P and NFET 102N can be formed adjacent to each other (as shown in FIGS. 1A, 1B, 1E, and 1F) and can have common elements, such as gate structures 118, gate spacers 120, STI regions 122, ESLs 124A and 124B, and ILD layers 126A and 126B. In some embodiments, there may be other FETs and/or structures (e.g., isolation structures; not shown) formed between PFET 102P and NFET 102N on substrate 104.

In some embodiments, fin bases 106Pa and 106Na can be formed by patterning and etching different portions of substrate 104. Thus, fin bases 106Pa and 106Na can include materials similar to that of substrate 104. In some embodiments, fin bases 106Pa can include n-type dopants (e.g., phosphorus or arsenic) and fin bases 106Na can include p-type dopants (e.g., boron, indium, aluminum, or gallium). In some embodiments, adjacent fin bases 106Pa can be spaced apart from each by a distance D1 (e.g., about 10 nm to about 15 nm), which is less than a distance D2 (e.g., about 20 nm to about 25 nm) between adjacent fin bases 106Na. Fin bases 106Pa and 106Na can be formed with such distances D1 and D2 between them to form S/D region 114N with a larger volume than S/D region 114P to achieve substantially similar device characteristics (e.g., similar threshold voltages) from PFET 102 and NFET 102N.

Fin structures 106Pb and 106Nb can be formed on fin bases 106Pa and 106Na, respectively, and can extend along an X-axis. The dashed rectangular boxes in FIGS. 1B, 1E, and 1F represent fin structures 106Pb and 106Nb disposed under gate structures 118, which are not visible in FIGS. 1B, 1E, and 1F. In some embodiments, portions of fin structures 106Pb and 106Nb under S/D regions 114P and 114N, respectively, can have heights shorter than heights of portions of fin structures 106Pb and 106Nb under gate structures 118, as shown in FIGS. 1B-1F.

In some embodiments, fin structures 106Pb form the channel regions of PFET 102P under gate structures 118 and can include an epitaxially-grown semiconductor material, such as SiGe having a Ge atom concentration of about 10 atomic % to about 20 atomic %. In some embodiments, fin structures 106Pb can have a fin height H1 of about 30 nm to about 80 nm along a Z-axis and a fin width W1 of about 8 nm to about 12 nm along a Y-axis. Within these ranges of fin height H1 and fin width W1, adequate device current can be generated and conducted through fin structures 106Pb without compromising the size and manufacturing cost of semiconductor device 100.

In some embodiments, fin structures 106Nb form the channel regions of NFET 102N under gate structures 118 and can include an epitaxially-grown semiconductor material, such as Si without any concentration of Ge atoms. In some embodiments, fin structures 106Nb can have a fin height H2 of about 30 nm to about 80 nm along a Z-axis and a fin width W2 of about 4 nm to about 8 nm along a Y-axis. Within these ranges of fin height H2 and fin width W2, adequate device current can be generated and conducted through fin structures 106Nb without compromising the size and manufacturing cost of semiconductor device 100.

In some embodiments, fin width W1 can be greater than fin width W2 by about 1 nm to about 5 nm and a ratio (W1:W2) between W1 and W2 can be about 1.1 to about 2. Fin structures 106Pb and 106Nb can be formed with such relative fin widths to achieve similar carrier mobility, thus achieving similar electrical characteristics in fin structures 106Pb and 106Nb. Otherwise, if fin widths of fin structures 106Pb and 106Nb are similar to each other, the carrier mobility (e.g., hole mobility) in fin structures 106Pb can be different (e.g., lower) than the carrier mobility (e.g., electron mobility) in fin structures 106Nb due to the different materials (e.g., SiGe and Si) of fin structures 106Pb and 106Nb. In some embodiments, fin structures 106Pb and 106Nb can be formed with fin heights H1 and H2 substantially equal to each other so that contact structures 116P and 116N can be formed at substantially similar depths into S/D regions 114P and 114N, respectively, to be in contact with adjacent fin structures 106Pb and 106Nb under gate structures 118, as shown in FIGS. 1B, 1E, and 1F.

In some embodiments, fin capping layers 108P can be disposed on and in contact with (i) sidewalls of fin structures 106Pb, as shown in FIGS. 1A, 1B, 1E, and 1F, (ii) top surfaces of fin structures 106Pb that are under gate spacers 120, as shown in FIG. 1C, and (iii) top surfaces of STI regions 122 in PFET 102P, as shown in FIGS. 1A and 1B. In some embodiments, depending on the method of forming fin capping layers 108P, fin capping layers 108P can be disposed on sidewalls of fin structures 106Pb, but not on top surfaces of STI regions 122, as shown in FIGS. 1E and 1F (described in detail below). The presence of fin capping layers 108P on the sidewalls of fin structures 106Pb can prevent or mitigate the strain induced by fin barrier layers 110P on fin structures 106Pb due to lattice mismatch between the material (e.g., SiGe) of fin structures 106Pb and the material (e.g., SiO₂) of fin barrier layers 110P. Such strain can induce crystal defects, such as dislocations and voids in fin structures 106Pb, which can degrade the performance of PFET 102P (e.g., increase threshold voltage). Thus, with the use of fin capping layers 108P, the interface between fin structures 106Pb and fin barrier layers 110P can be improved, thus improving the performance of PFET 102P.

In some embodiments, fin capping layers 108P can include an oxide (e.g., silicon germanium oxide (SiGeOₓ)) of the material (e.g., SiGe) of fin structures 106Pb to reduce the strain between fin structures 106Pb and fin barrier layers 110P. In some embodiments, fin capping layers 108P can include SiGeOₓ with a Ge atom concentration of about 1 atomic % to about 20 atomic %. Within this range of Ge atom concentration, the mobility of hole carriers in fin structures 106Pb can be adequately increased to improve the performance of PFET 102P without compromising the size and manufacturing cost of semiconductor device 100. In some embodiments, fin capping layers 108P can have a thickness of about 1 nm to about 2 nm. Within this range of thickness, fin capping layers 108P can adequately improve the interface between fin structures 106Pb and fin barrier layers 110P without compromising the size and manufacturing cost of semiconductor device 100.

In some embodiments, fin capping layers 108N can be disposed on and in contact with (i) sidewalls of fin structures 106Nb, as shown in FIGS. 1A, 1B, 1E, and 1F, (ii) top surfaces of fin structures 106Nb that are under gate spacers 120, as shown in FIG. 1D, and (iii) top surfaces of STI regions 122 in NFET 102P, as shown in FIGS. 1A and 1B. In some embodiments, depending on the method of forming fin capping layers 108N, fin capping layers 108N can be disposed on sidewalls of fin structures 106Nb, but not on top surfaces of STI regions 122, as shown in FIG. 1F (described in detail below). The presence of fin capping layers 108N on the sidewalls of fin structures 106Nb can improve the interface between fin structures 106Nb and fin barrier layers 110N, thus improving the performance of NFET 102N. In some embodiments, fin capping layers 108N can include the same semiconductor material (e.g., Si) of fin structures 106Nb. In some embodiments, fin capping layers 108N can include an undoped Si layer.

In some embodiments, fin barrier layers 110P can be disposed on and in contact with fin capping layers 108P, as shown in FIGS. 1B, 1E, and 1F. In some embodiments, in the absence of fin capping layers 108P on top surfaces of STI regions in PFET 102P, portions of fin barrier layers 110P can be disposed on and in contact with top surfaces of STI regions in PFET 102P, as shown in FIG. 1E. In some embodiments, depending on the method of forming fin barrier layers 110P, fin barrier layers 110P can be disposed on fin capping layers 108P, but not on top surfaces of STI regions 122, as shown in FIG. 1F (described in detail below). Fin barrier layers 110P can prevent or mitigate the out-diffusion of Ge atoms and/or dopant atoms from fin structures 106Pb during the formation of semiconductor device 100.

Similarly, in some embodiments, fin barrier layers 110N can be disposed on and in contact with fin capping layers 108N, as shown in FIGS. 1B, 1E, and 1F. In some embodiments, depending on the method of forming fin barrier layers 110N, fin barrier layers 110N can be disposed on fin capping layers 108N, but not on top surfaces of STI regions 122, as shown in FIG. 1F (described in detail below). Fin barrier layers 110P can prevent or mitigate the out-diffusion of dopant atoms from fin structures 106Nb during the formation of semiconductor device 100. In some embodiments, fin barrier layers 110P and 110N can be portions of a single continuous layer, as shown in FIGS. 1B and 1E. In some embodiments, fin barrier layers 110P and 110N can include a dielectric oxide material, such as SiO₂.

In some embodiments, fin spacers 112P can be disposed on and in contact with fin barrier layers 110P and can protect fin barrier layers 110P, fin capping layers 108P, and fin structures 106Pb from processing chemicals during the formation of semiconductor device 100. Similarly, in some embodiments, fin spacers 112N can be disposed on and in contact with fin barrier layers 110N and can protect fin barrier layers 110N, fin capping layers 108N, and fin structures 106Nb from processing chemicals during the formation of semiconductor device 100. In some embodiments, fin spacers 112P and 112N can be used to control the epitaxial lateral growth of S/D regions 114P and 114N along a Y-axis and prevent S/D regions 114P and 114N from merging with adjacent S/D regions during their epitaxial growth. In some embodiments, fin spacers 112P can include first dielectric layers 112Pa disposed on fin barrier layers 110P and second dielectric 112Pb disposed on first dielectric layers 112Pa. Similarly, in some embodiments, fin spacers 112N can include first dielectric layers 112Na disposed on fin barrier layers 110N and second dielectric 112Nb disposed on first dielectric layers 112Na. In some embodiments, first dielectric layers 112Pa and 112Na and second dielectric layers 112Pb and 112Nb can include dielectric materials, such as silicon nitride (SiN), silicon carbon nitride (SiCN), silicon carbon oxynitride (SiCON), and other suitable dielectric nitride materials.

S/D regions 114P can be disposed on fin structures 106Pb that are not covered by gate structures 118 in PFET 102P. As S/D regions 114P are formed by the merging of two epitaxial structures grown on two fin structures 106Pb, S/D regions 114P can be referred to as “merged S/D regions 114P.” In some embodiments, each S/D region 114P can include S/D sub-regions 114Pa and 114Pb. S/D sub-regions 114Pb can act as capping layers to protect S/D sub-regions 114Pa and prevent out-diffusion of p-type dopants from S/D sub-regions 114Pa during any subsequent processing of PFET 102P. In some embodiments, 114Pa and 114Pb can include epitaxially-grown SiGe and can differ from each other based on a relative concentration of Ge atoms with respect to Si atoms. In some embodiments, S/D sub-regions 114Pa can include a Ge atom concentration of about 35 atomic % to about 60 atomic % with any remaining atomic % being Si atoms. In some embodiments, S/D sub-regions 114Pb can include a Ge atom concentration of about 45 atomic % to about 55 atomic % with any remaining atomic % being Si atoms. In some embodiments, S/D sub-regions 114Pa and 114Pb can differ from each other based on p-type dopant (e.g., boron atoms) concentrations. In some embodiments, S/D sub-regions 114Pa can include a boron dopant concentration of about 8×1020 to about 3×1021 atoms/cm³. In some embodiments, S/D sub-regions 114Pb can include a boron dopant concentration of about 1×1021 to about 2×1021 atoms/cm³.

S/D regions 114N can be disposed on fin structures 106Nb that are not covered by gate structures 118 in NFET 102N. As S/D regions 114N are formed by the merging of two epitaxial structures grown on two fin structures 106Nb, S/D regions 114N can be referred to as “merged S/D regions 114N.” In some embodiments, each S/D region 114N can include S/D sub-regions 114Na and 114Nb. In some embodiments, S/D sub-regions 114Na and 114Nb can include epitaxially-grown Si without any Ge atoms and can differ from each other based on n-type dopant (e.g., phosphorus atoms) concentrations. In some embodiments, S/D sub-regions 114Na can include a phosphorus dopant concentration of about 5×1020 to about 4×1021 atoms/cm³. In some embodiments, S/D sub-regions 114Nb can include a phosphorus dopant concentration of about 1×1021 to about 3×1021 atoms/cm³. Similar to S/D sub-regions 114Pb, S/D sub-regions 114Nb can act as capping layers to protect S/D sub-region 114Na and prevent out-diffusion of n-type dopants from S/D sub-regions 114Na during any subsequent processing of NFET 102N. In some embodiments, S/D regions 114N can have a height greater than a height of S/D regions 114P. The relative heights of S/D regions 114P and 114N can be controlled by the relative dimensions of fin spacers 112P and 112N. For example, to achieve the above mentioned relative heights of S/D regions 114P and 114N, fin spacers 112P can be formed with a height H3 greater than a height H4 of fin spacers 112N.

In some embodiments, contact structures 116P and 116N can be disposed on S/D regions 114P and 114N, respectively, to electrically connect S/D regions 114P and 114N to other elements of semiconductor device 100 and/or to other active and/or passive devices (not shown) in an integrated circuit. In some embodiments, each contact structure 116P can include (i) a silicide layer 116Pa disposed on S/D region 114P, (ii) a contact plug 116Pb disposed on silicide layer 116Pa, and (iii) a diffusion barrier layer 116Pc disposed on sidewalls of contact plug 116Pb and surrounding contact plug 116Pb. Similarly, in some embodiments, each contact structure 116N can include (i) a silicide layer 1168Na disposed on S/D region 114N, (ii) a contact plug 116Nb disposed on silicide layer 116Na, and (iii) a diffusion barrier layer 116Pc disposed on sidewalls of contact plug 116Nb and surrounding contact plug 116Nb.

In some embodiments, silicide layers 116Pa can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof. In some embodiments, silicide layers 116Na can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof. In some embodiments, contact plugs 116Pb and 116Nb can include conductive materials, such as cobalt (Co), tungsten (W), ruthenium (Ru), aluminum (Al), molybdenum (Mo), iridium (Ir), nickel (Ni), Osmium (Os), rhodium (Rh), other suitable conductive materials, and a combination thereof.

Diffusion barrier layers 116Pc and 116Nc can prevent or minimize (i) the oxidation of contact plugs 116Pb and 116Nb by preventing the diffusion of oxygen atoms from adjacent structures (e.g., ILD layers 126A and 126B) to contact plugs 116Pb and 116Nb, and (ii) the diffusion of metal atoms from contact plugs 116Pb and 116Nb into gate structures 118. In some embodiments, diffusion barrier layers 116Pc and 116Nc can include a dielectric material, such as SiO₂, SiN, SiON, SiCN, SiOCN, aluminum oxide (Al₂O₃), aluminum oxynitride (AlON), zirconium oxide (ZrO₂), hafnium oxide (HfO₂), titanium oxide (TiO₂), zirconium aluminum oxide (ZrAlO), zinc oxide (ZnO), and other suitable dielectric materials.

Gate structures 118 can be disposed on fin structures 106Pb and 106Nb, as shown in FIGS. 1C and 1D. In some embodiments, each gate structure 118 can include (i) an interfacial oxide (IL) layer 118A disposed on fin structures 106Pb and 106Nb, (ii) a high-k gate dielectric layer 118B disposed on IL layer 118A, and (iii) a conductive layer 118C disposed on high-k gate dielectric layer 118B. In some embodiments, IL layers 118A can include SiO₂, SiGeOₓ, or germanium oxide (GeOₓ). In some embodiments, high-k gate dielectric layers 118B can include a high-k dielectric material, such as HfO₂, TiO₂, hafnium zirconium oxide (HfZrO), tantalum oxide (Ta₂O₃), hafnium silicate (HfSiO₄), ZrO₂, ZrAlO, zirconium silicate (ZrSiO₂), lanthanum oxide (La₂O₃), Al₂O₃, ZnO, hafnium zinc oxide (HfZnO), and yttrium oxide (Y₂O₃).

In some embodiments, gate structures 118 may not include IL layers 118A, as shown in FIGS. 1H and 1I. Instead of high-k gate dielectric layers 118B being disposed on IL layers 118A, high-k gate dielectric layers 118B can be disposed directly on fin barrier layers 110P and 110N, as shown in FIGS. 1H and 1L. In such structures, portions of fin barrier layers 110P and 110N and fin capping layers 108P and 108N under gate structures 118 can function as gate oxide layers. In some embodiments, FETs 102P and 102N can have the cross-sectional views of FIG. 1H and 1I when FETs 102P and 102N are used as input/output (I/O) FETs in an I/O device area of an integrated circuit and configured to handle I/O voltages/currents of semiconductor device 100. In some embodiments, FETs 102P and 102N can have the cross-sectional views of FIG. 1C and ID when FETs 102P and 102N are used as non-I/O FETs in a core device area (also referred to as logic device area) of an integrated circuit. In some embodiments, the non-I/O FETs can be a core device, a logic device, or a memory device that are not configured to handle I/O voltages/currents of semiconductor device 100 directly.

In some embodiments, conductive layers 118C can be multi-layered structures. The different layers of conductive layers 118C are not shown for simplicity. Each of conductive layers 118C can include a work function metal (WFM) layer disposed on high-k gate dielectric layers 118B and a gate metal fill layer disposed on the WFM layer. In some embodiments, the WFM layers can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu), titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials. The gate metal fill layers can include a suitable conductive material, such as W, Ru, Mo, Co, Al, Ir, Ni, copper (Cu), metal alloys, and a combination thereof.

In some embodiments, gate structures 118 can be electrically isolated from adjacent contact structure 116P and 116N by gate spacers 120. In some embodiments, each gate spacers 120 can include a first dielectric layer 120A disposed on high-k dielectric layer 118B and a second dielectric 120B disposed on first dielectric layer 120A. In some embodiments, first dielectric layers 120A and second dielectric layers 120B can include dielectric materials, such as SiN, SiCN, SiCON, and other suitable dielectric materials. In some embodiments, first dielectric layers 112Pa, 112Na, and 120A are portions of the same spacer material layer and can be in contact with each other. In some embodiments, second dielectric layers 112Pb, 112Nb, and 120B are portions of the same spacer material layer and can be in contact with each other.

In some embodiments, STI regions 122 can provide electrical isolation to fin bases 106Pa and 106Na from adjacent structures integrated with or deposited onto substrate 104. In some embodiments, STI regions 122 can have top surfaces substantially coplanar with top surfaces of fin bases 106Pa and 106Na. STI regions 122 can have a dielectric material, such as SiO₂, SiN, SiON, SiOC, SiCN, and SiOCN. In some embodiments, ESLs 124A can be disposed directly on S/D regions 114P and 114N, fin spacers 112P and 112N, fin barrier layers 110P and 110N, and gate spacers 120, as shown in FIGS. 1A-1E. In some embodiments, ESLs 124A can be disposed directly on STI regions 122, as shown in FIG. 1F. In some embodiments, (i) ILD layers 126A can be disposed directly on ESLs 124A, (ii) ESLs 124B can be disposed directly on ILD layers 126A and can surround contact structures 116P and 116N, and (iii) ILD layers 126B can be disposed directly on ESLs 124B and can surround contact structures 116P and 116N. In some embodiments, ESLs 124A and 124B and ILD layers 126A and 126B can include dielectric material, such as SiO₂, SiN, SiON, SiCN, SiOC, and SiOCN.

Referring to FIG. 1G, semiconductor device 100 can have the cross-sectional view of FIG. 1G instead of FIGS. 1B, 1E, and 1F, according to some embodiments. FIG. 1C illustrates a cross-sectional view of semiconductor device 100 along line B-B of FIG. 1G, with additional structures that are not visible in FIG. 1G, according to some embodiments. FIG. 1D illustrates a cross-sectional view of semiconductor device 100 along line C-C of FIG. 1G, with additional structures that are not visible in FIG. 1G, according to some embodiments. The discussion of elements in FIGS. 1A-1G with the same annotations applies to each other, unless mentioned otherwise. In some embodiments, PFET 102P can have diamond-shaped S/D region 115P epitaxially grown on one fin structure 106Pb, instead of merged S/D region 114P on two fin structures 106Pb. Similarly, NFET 102N can have oval-shaped S/D region 115N epitaxially grown on one fin structure 106Nb, instead of merged S/D region 114N on two fin structures 106Nb. S/D region 115N can have a larger volume than S/D region 115P and can have a height greater than a height of S/D region 115P.

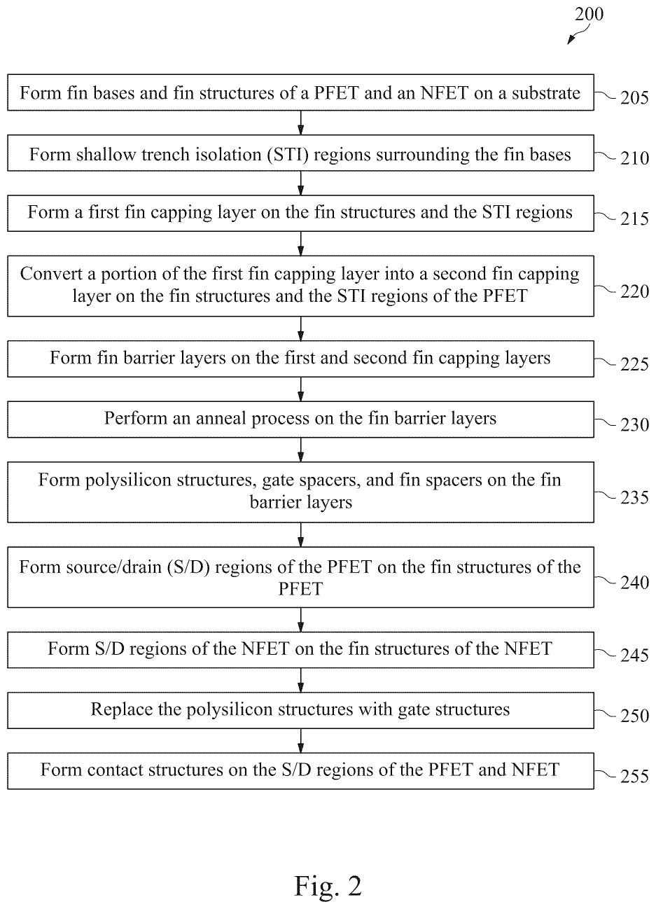

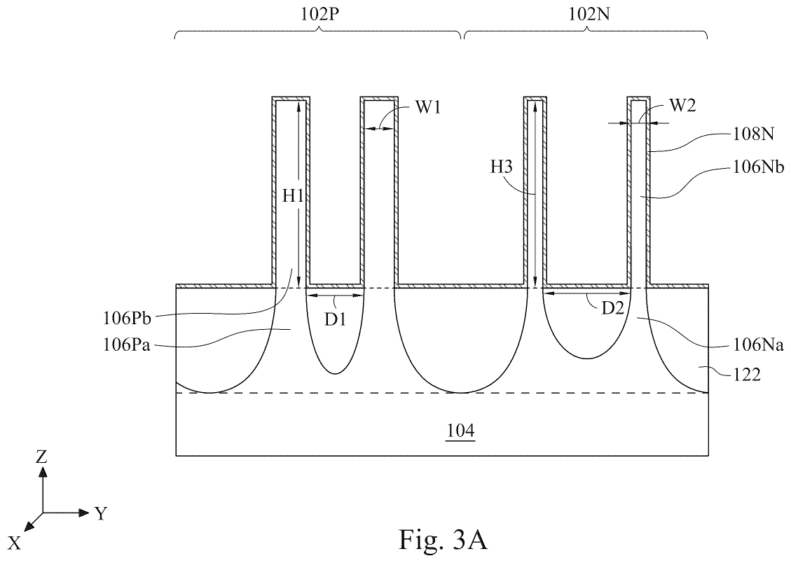

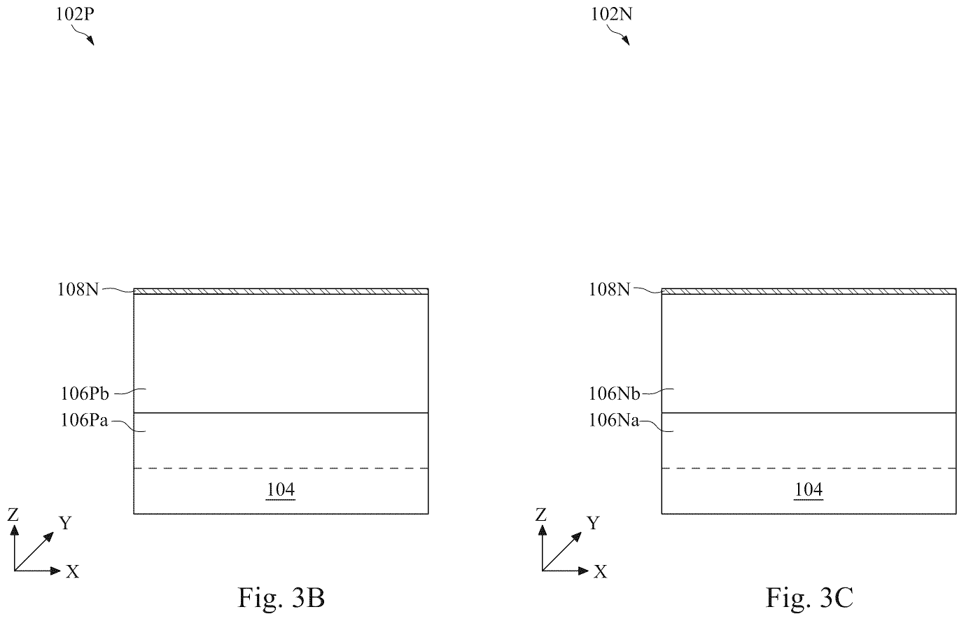

FIG. 2 is a flow diagram of an example method 200 for fabricating semiconductor device 100 as described above with reference to FIGS. 1A-1D, according to some embodiments. For illustrative purposes, the operations illustrated in FIG. 2 will be described with reference to the example fabrication process for fabricating semiconductor device 100 as illustrated in FIGS. 3A-16A, 3B-16B, and 3C-16C. FIGS. 3A-16A are cross-sectional views of semiconductor device 100 along line A-A of FIG. 1A at various stages of fabrication, according to some embodiments. FIGS. 3B-16B are cross-sectional views of semiconductor device 100 along lines B-B of FIGS. 1A and 1B at various stages of fabrication, according to some embodiments. FIGS. 3C-16C are cross-sectional views of semiconductor device 100 along lines C-C of FIGS. 1A and 1B at various stages of fabrication, according to some embodiments. Operations can be performed in a different order or not performed depending on specific applications. It should be noted that method 200 may not produce a complete semiconductor device 100. Accordingly, it is understood that additional processes can be provided before, during, and after method 200, and that some other processes may only be briefly described herein. The discussion of elements in FIGS. 1A-1D, 3A-16A, 3B-16B, and 3C-16C with the same annotations applies to each other, unless mentioned otherwise.

Referring to FIG. 2, in operation 205, fin bases and fin structures of a PFET and an NFET are formed on a substrate. For example, as described with reference to FIGS. 3A-3C, fin bases 106Pa and 106Na are formed on substrate 104 and fin structures 106Pb and 106Nb are formed on fin bases 106Pa and 106Na. In some embodiments, fin bases 106Pa and 106Na can be selectively and sequentially formed on different regions of substrate 104 in different processing steps. In some embodiments, the formation of fin bases 106Pa and fin structures 106Pb can be followed by the formation of fin bases 106Na and fin structures 106Nb and vice versa.

Referring to FIG. 2, in operation 210, STI regions are formed surrounding the fin bases. For example, as described with reference to FIGS. 3A-3C, STI regions 122 are formed surrounding fin bases 106Pa and 106Na. STI regions 122 are not visible in FIGS. 3B and 3C. STI regions 122 can be formed by depositing a dielectric material, such as SiO₂, SiN, SiON, SiOC, SiCN, and SiOCN (not shown) on and surrounding fin bases 106Pa and 106Na and fin structures 106Pb and 106Nb. The deposition of the dielectric material can be followed by an etching process on the dielectric material to form STI regions 122 with top surfaces substantially coplanar with top surfaces of fin bases 106Pa and 106Na, as shown in FIG. 3A.

Referring to FIG. 2, in operation 215, a first fin capping layer is formed on the fin structures and the STI regions. For example, as described with reference to FIGS. 3A-3C, first fin capping layer 108N is formed on fin structures 106Pb and 106Nb and on the top surfaces of STI regions 122. In some embodiments, the formation of first capping layer 108N can include depositing an undoped Si layer (e.g., an undoped polysilicon layer or an undoped crystalline Si layer on fin structures 106Pb and 106Nb and on the top surfaces of STI regions 122 using a Si precursor gas (e.g.,, silane (SiH₄) gas) in a chemical vapor deposition (CVD) process, an atomic layer deposition (ALD) process, or other suitable deposition process.

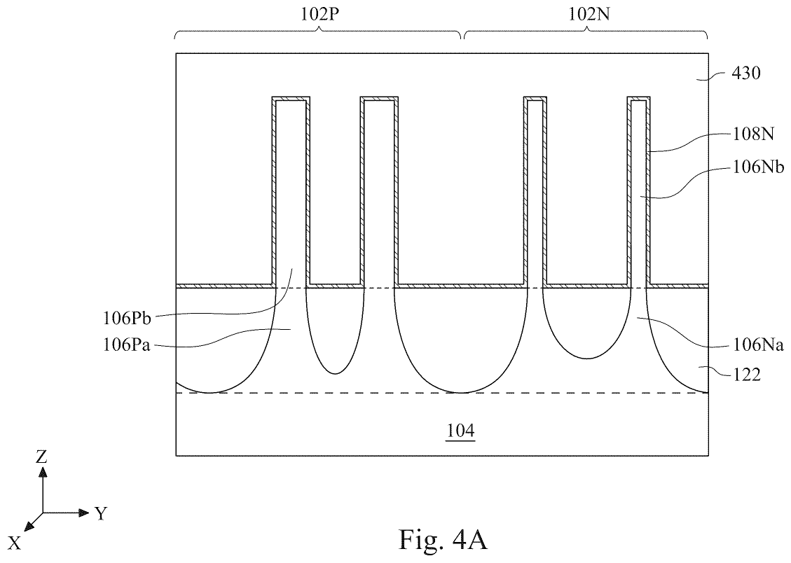

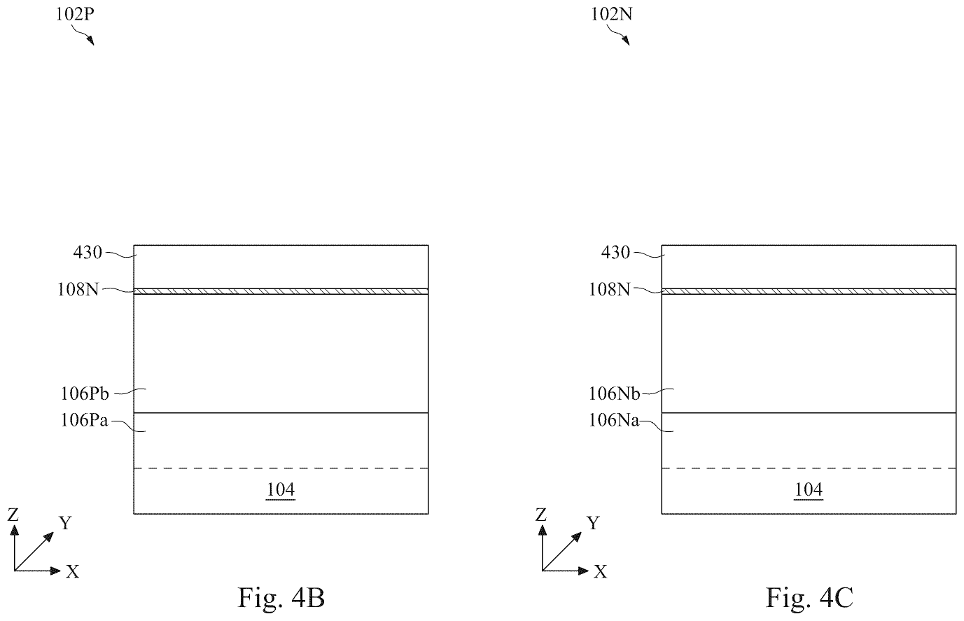

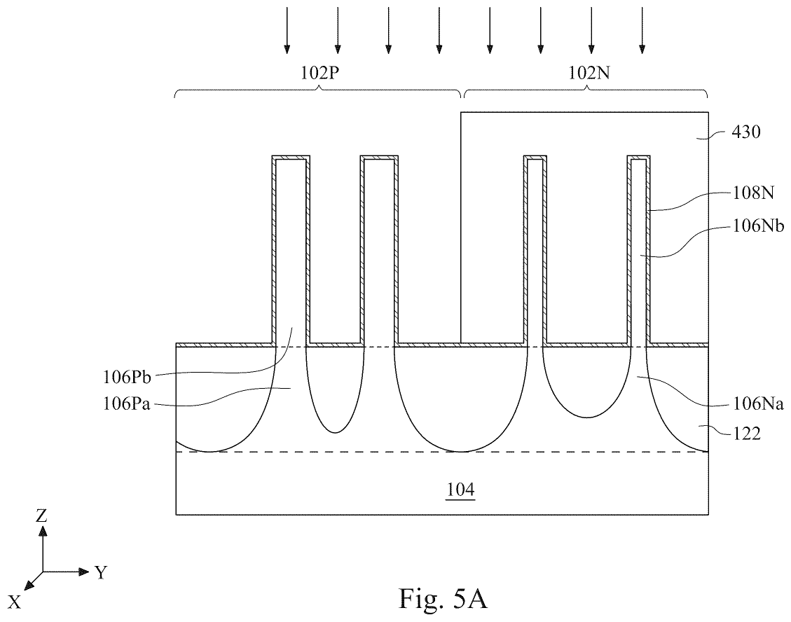

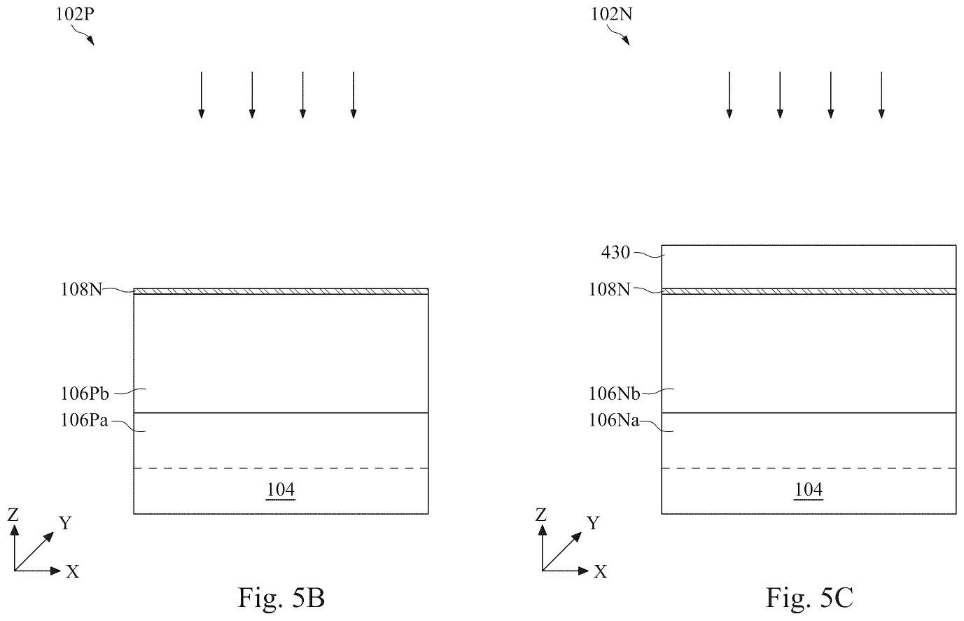

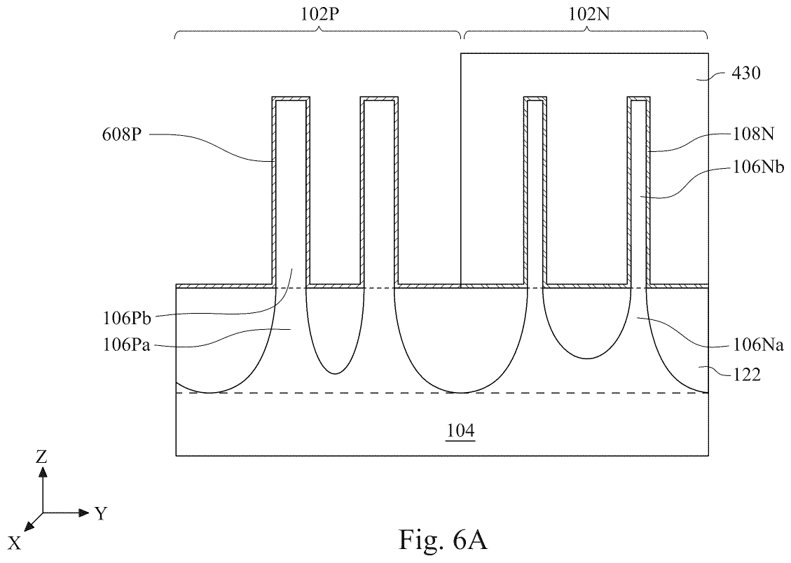

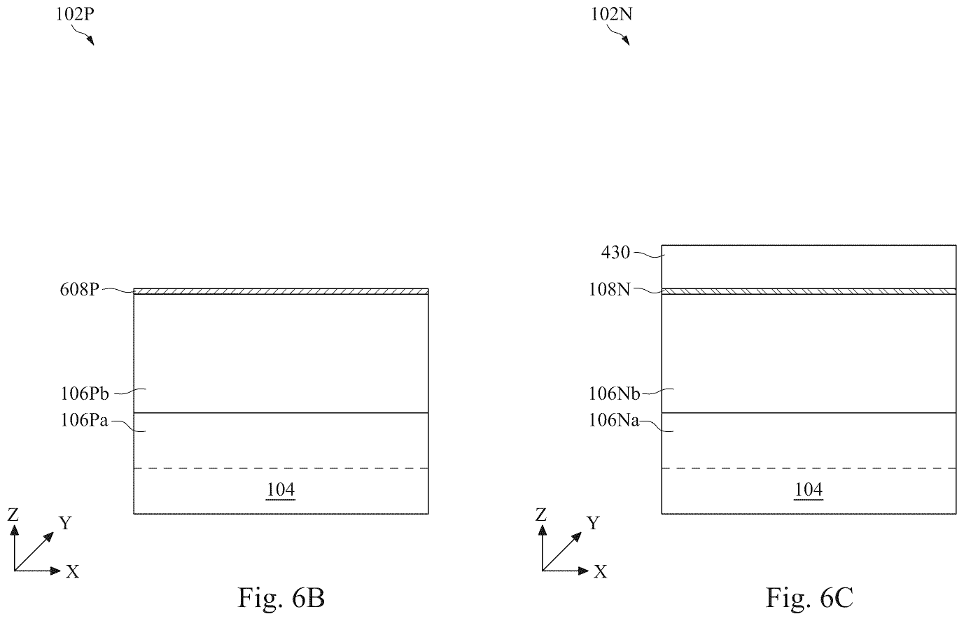

Referring to FIG. 2, in operation 220, a portion of the first fin capping layer is converted into a second fin capping layer on the fin structures and the STI regions of the PFET. For example, as described with reference to FIGS. 4A-4C, 5A-5C, and 6A-6C, a portion of first fin capping layer 108N is converted into a second fin capping layer 608P having a SiGe layer on fin structures 106Pb and on the top surfaces of STI regions 122 of PFET 102. The conversion of the portion of first fin capping layer 108N can include sequential operations of (i) depositing a masking layer 430 (e.g., SiN layer) on first fin capping layer 108N, as shown in FIGS. 4A-4C, (ii) etching a portion of masking layer 430 to expose the portion of first fin capping layer 108N on fin structures 106Pb and on STI regions 122 of PFET 102, as shown in FIGS. 5A-5C, and (iii) performing a doping process with Ge dopants using a Ge precursor gas (e.g., germane (GeH₄) gas) on the structures of FIGS. 5A-5C to convert the exposed portion of first fin capping layer 108N having undoped Si layer into second fin capping layer 608P having a SiGe layer with a Ge atom concentration of about 1 atomic % to about 20 atomic %, as shown in FIGS. 6A-6C. The doping process can be followed by the removal of masking layer 430 from fin capping layer 108N of NFET 102N.

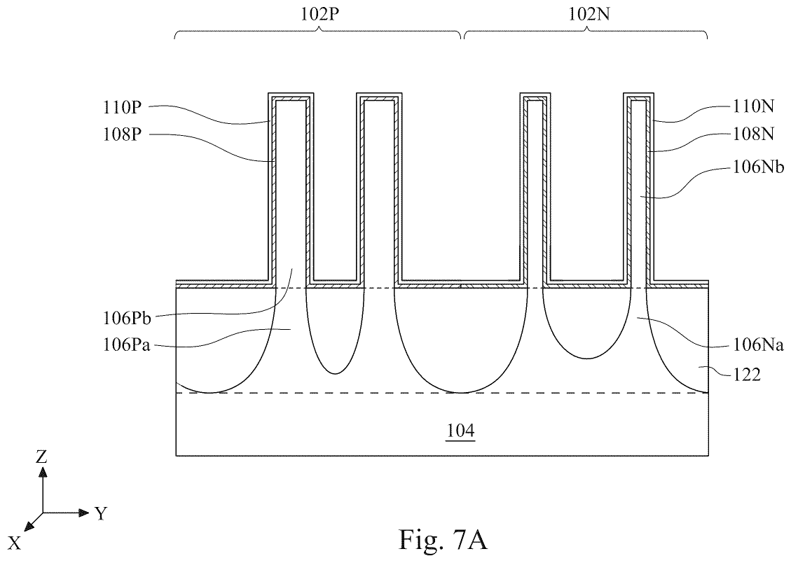

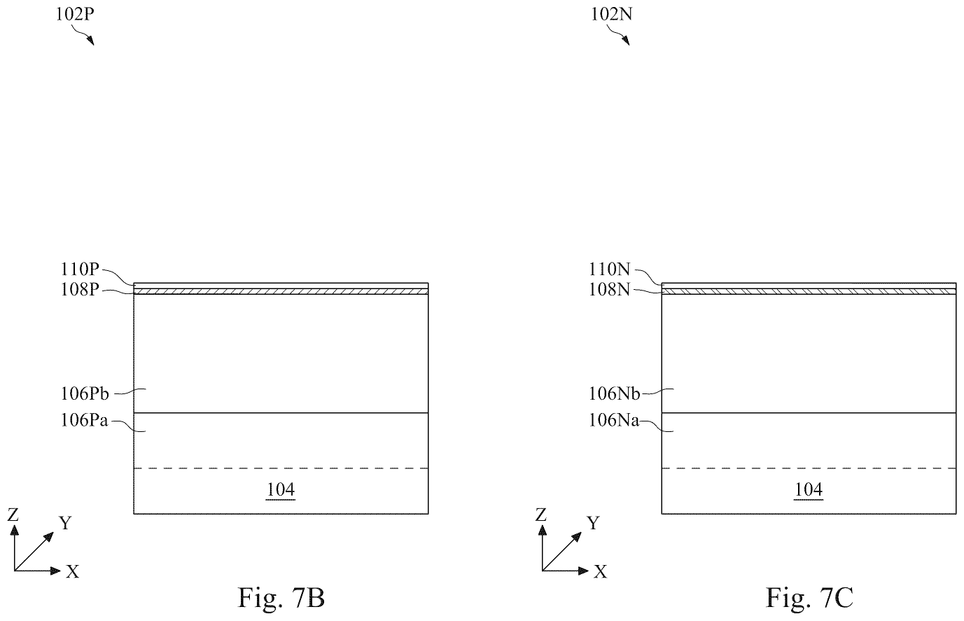

Referring to FIG. 2, in operation 225, fin barrier layers are formed on the first and second fin capping layers. For example, as described with reference to FIGS. 7A-7C, fin barrier layer 110N is formed on fin capping layer 108N and fin barrier layer 110P is formed on fin capping layer 608P, which oxidizes to form fin capping layer 108P having SiGeOₓ during the formation of fin barrier layers 110P and 110N. In some embodiments, the formation of fin barrier layers 110P and 110N can include depositing a SiO₂ layer on fin capping layers 608P and 108N using a precursor gas, such as tetraethylorthosilicate (TEOS) gas in a CVD process at a temperature of about 650 °C to about 750 °C. In some embodiments, oxygen atoms from the SiO₂ layer of fin barrier layer 110P can diffuse into fin capping layer 608P and oxidize the SiGe layer of fin capping layer 608P to form SiGeOₓ layer of fin capping layer 108P.

In some embodiments, the formation of fin barrier layers 110P and 110N can include sequential operations of (i) depositing a Si layer (not shown) on fin capping layers 608P and 108N using a Si precursor gas, such as tetraethylorthosilicate (TEOS) gas or a SiH₄ gas in a CVD process, and (ii) performing an anneal process on the Si layer at a temperature of about 600 °C to about 1100 °C in an oxygen ambient or in a steam and oxygen ambient. In some embodiments, the SiGe layer of fin capping layer 608P can be oxidized during the anneal process to form SiGeOₓ layer of fin capping layer 108P.

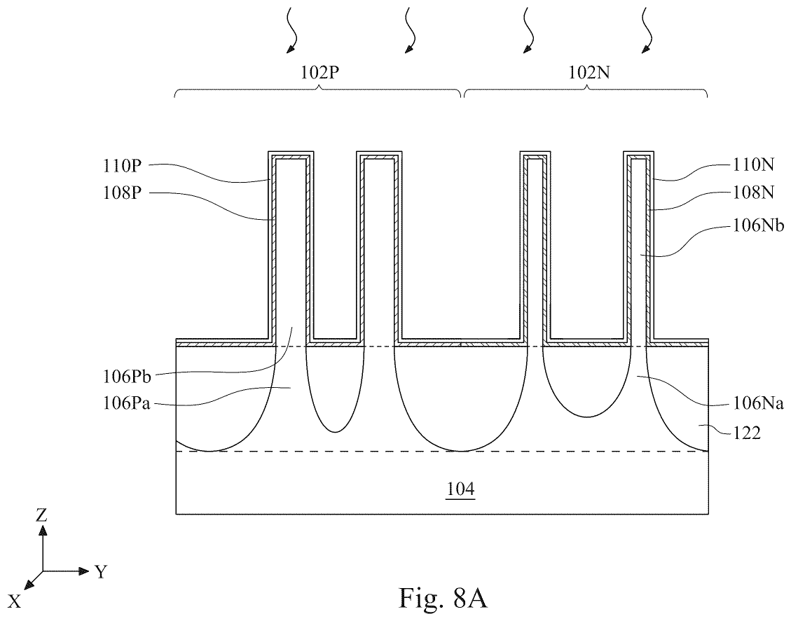

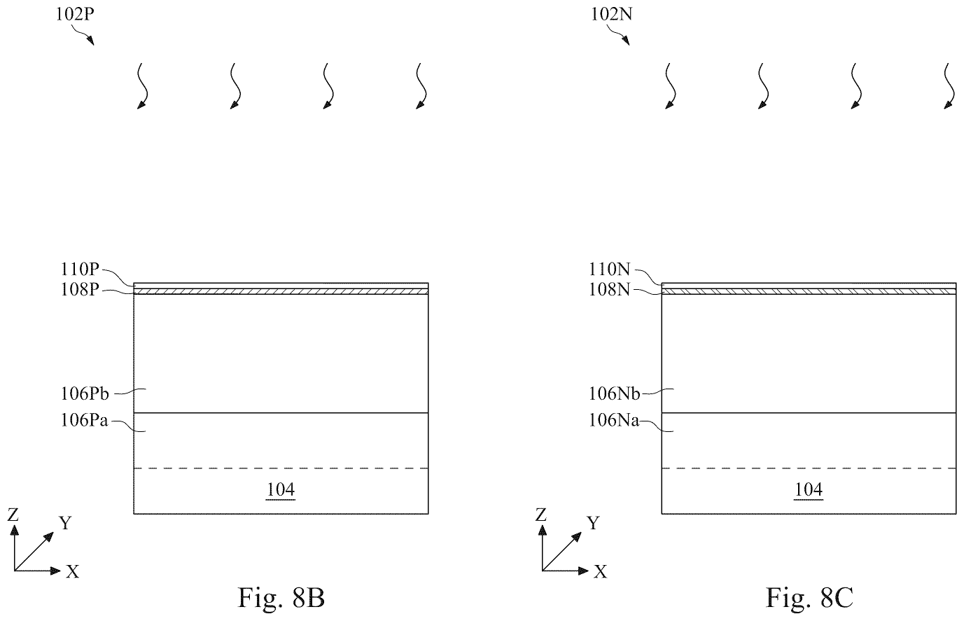

Referring to FIG. 2, in operation 230, an anneal process is performed on the fin barrier layers. For example, as described with reference to FIGS. 8A-8C, an anneal process is performed on fin barrier layers 110P and 110N at a temperature of about 500 °C to about 1000 °C and a pressure of about 10 torr to about 20 torr in a hydrogen ambient. Within these ranges of temperature and pressure, hydrogen atoms can passivate the dangling bonds on the surfaces of fin barrier layers 110P and 110N and/or fin capping layers 108P and 108N to reduce defects (e.g., traps) in fin barrier layers 110P and 110N and/or fin capping layers 108P and 108N.

Reducing these defects can prevent or mitigate current leakage from fin structures 106Pb and 106Nb through traps in fin barrier layers 110P and 110N and/or fin capping layers 108P and 108N.

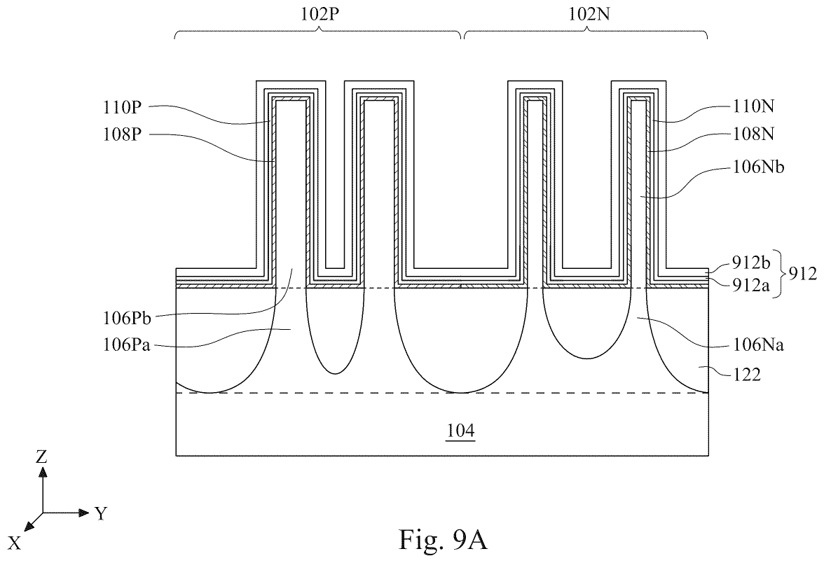

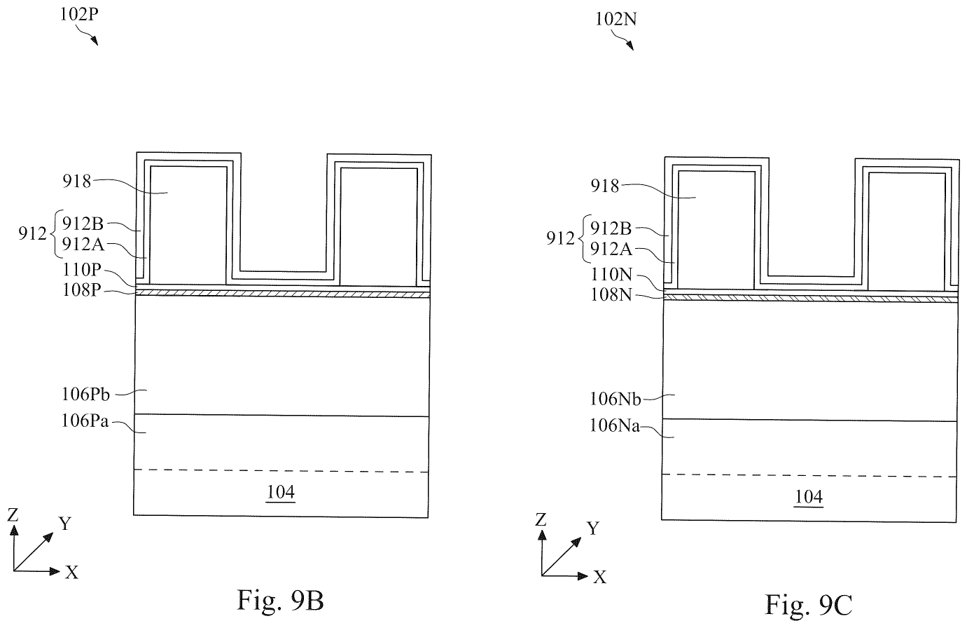

Referring to FIG. 2, in operation 235, polysilicon structures, gate spacers, and fin spacers are formed on the fin barrier layers. For example, as described with reference to FIGS. 9A-9C, 10A-10C, and 11A-11C, polysilicon structures 918, gate spacers 120, and fin spacers 112P and 112N are formed on fin barrier layers 110P and 110N. Polysilicon structures 918 can be formed by patterning and etching a polysilicon layer (not shown) deposited on the structures of FIGS. 8A-8C, as shown in FIGS. 9B and 9C (polysilicon structures 918 not visible in FIG. 9A). The formation of polysilicon structures 918 can be followed by the formation of gate spacers 120 and fin spacers 112P and 112N.

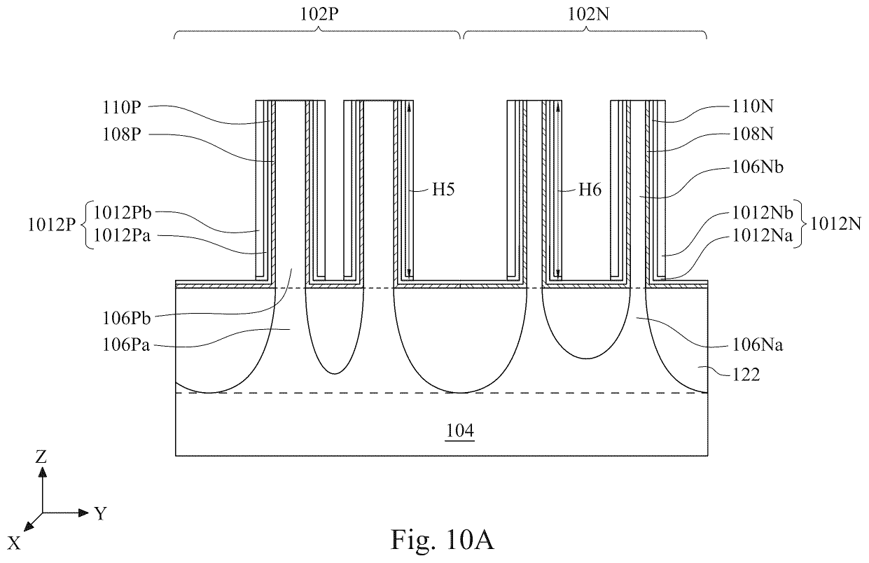

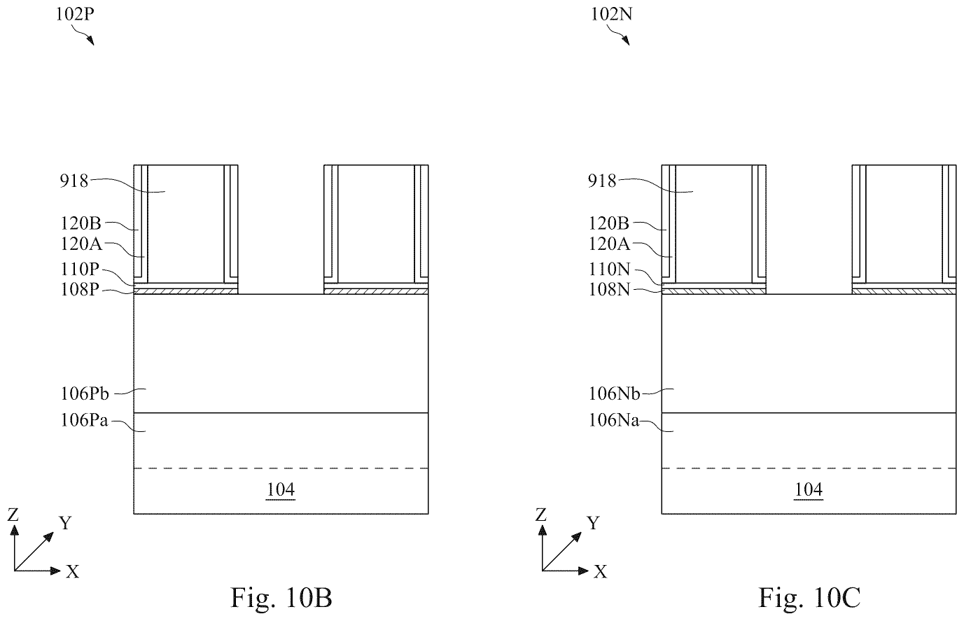

In some embodiments, gate spacers 120 and fin spacers 112P and 112N can be formed from the same spacer material layer 912 at different stages of selectively etching spacer material layer 912. Spacer material layer 912 can include first and second dielectric layers 912A and 912B having SiO₂, SiN, SiON, SiCO, SiCN, SiCON, and other suitable insulating materials. The formation of gate spacers 120 and fin spacers 112P and 112N can start with depositing a substantially conformal spacer material layer 912 directly on polysilicon structures 918 and fin barrier layers 110P and 110N, as shown in FIGS. 9A-9C. The deposition of spacer material layer 912 can be followed by a first etching process to etch (i) portions of spacer material layer 912 from top surfaces of polysilicon structures 918 and fin barrier layers 110P and 110N, and (ii) portions of fin barrier layers 110P and 110N and fin capping layers 108P and 108N from top surfaces of fin structures 106Pb and 106Nb to form the structures of FIGS. 10A-10C. Thus, after the first etching process, gate spacers 120 can be formed, as shown in FIGS. 10B and 10C (gate spacers 120 not visible in FIG. 10A), and fin spacers 1012P and 1012N on fin barrier layers 110P and 110N and along sidewalls of fin structures 106Pb and 106Nb can be formed, as shown in FIG. 10A (fin spacers 1012P and 1012N not visible in FIGS. 10B and 10B).

In some embodiments, the first etching process can be an anisotropic dry etching process and can have a higher etching rate along a Z-axis than along an X-axis or a Y-axis. As a result, spacer material layer 912 on the top surfaces of polysilicon structures 918 and fin barrier layers 110P and 110N and can be removed, while fin spacers 1012P and 1012N along sidewalls of fin structures 106Pb and 106Nb can remain. The etching gases used in the first etching process can have a higher selectivity for spacer material layer 912 than for polysilicon structures 918 and fin structures 106Pb and 106Nb.

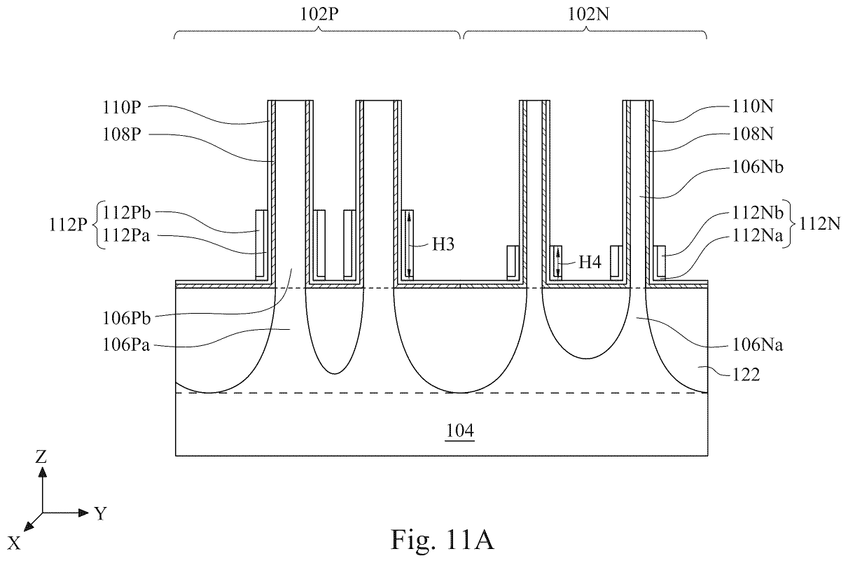

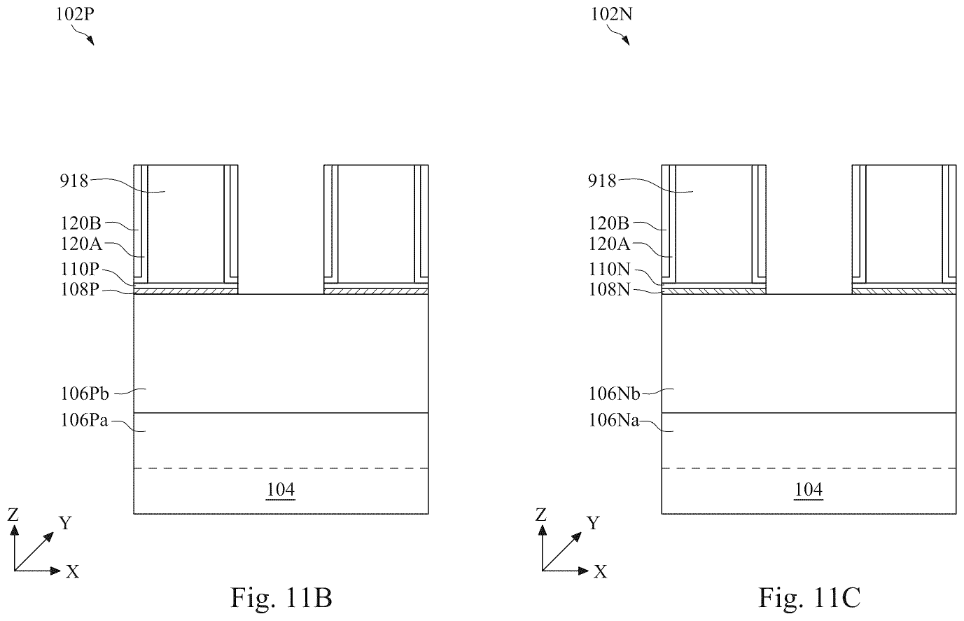

The first etching process can be followed by a second etching process to selectively etch fin spacers 1012P with a height H5 to form shorter fin spacers 112P with height H3, as shown in FIG. 11A (fin spacers 112P not visible in FIGS. 11B and 11C). In some embodiments, during the second etching process, NFET 102N and polysilicon structures 918 of PFET 102P can be protected with a masking layer (not shown), which can be formed after the first etching process. In some embodiments, the second etching process can include a plasma-based dry etching process using etching gases, such as carbon tetrafluoride (CF₄), sulfur dioxide (SO₂), hexafluoroethane (C₂F₆), chlorine (Cl₂), nitrogen trifluoride (NF₃), sulfur hexafluoride (SF₆), and hydrogen bromide (HBr), with mixture gases, such as hydrogen (H₂), oxygen (O₂), nitrogen (N₂), and argon (Ar).

The second etching process can be followed by a third etching process to selectively etch fin spacers 1012N with a height H6 to form shorter fin spacers 112N with height H4, as shown in FIG. 11A (fin spacers 112N not visible in FIGS. 11B and 11C). In some embodiments, during the third etching process, PFET 102P and polysilicon structures 918 of NFET 102N can be protected with a masking layer (not shown), which can be formed after the second etching process. In some embodiments, the third etching process can include a plasma-based dry etching process using etching gases, such as CF₄, SO₂, C₂F₆, Cl₂, NF₃, SF₆, and HBr, with mixture gases, such as H₂, O₂, N₂, and Ar.

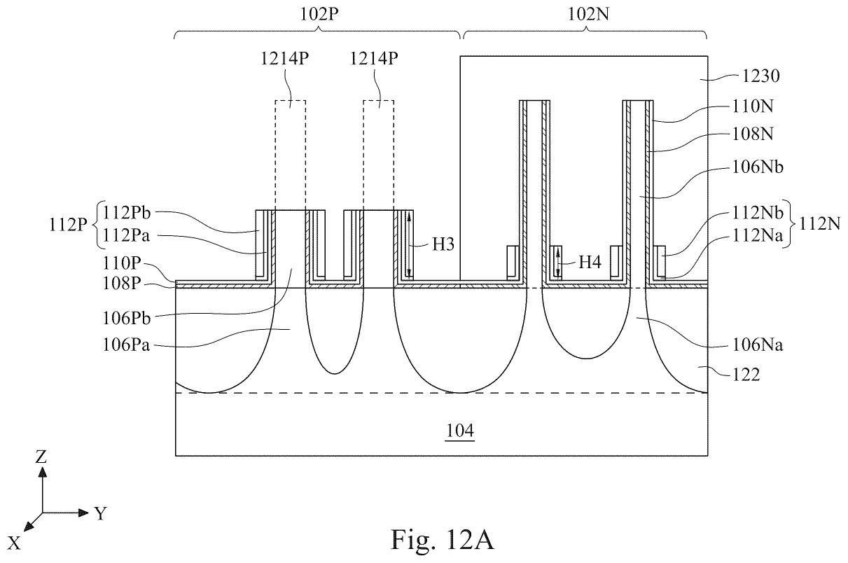

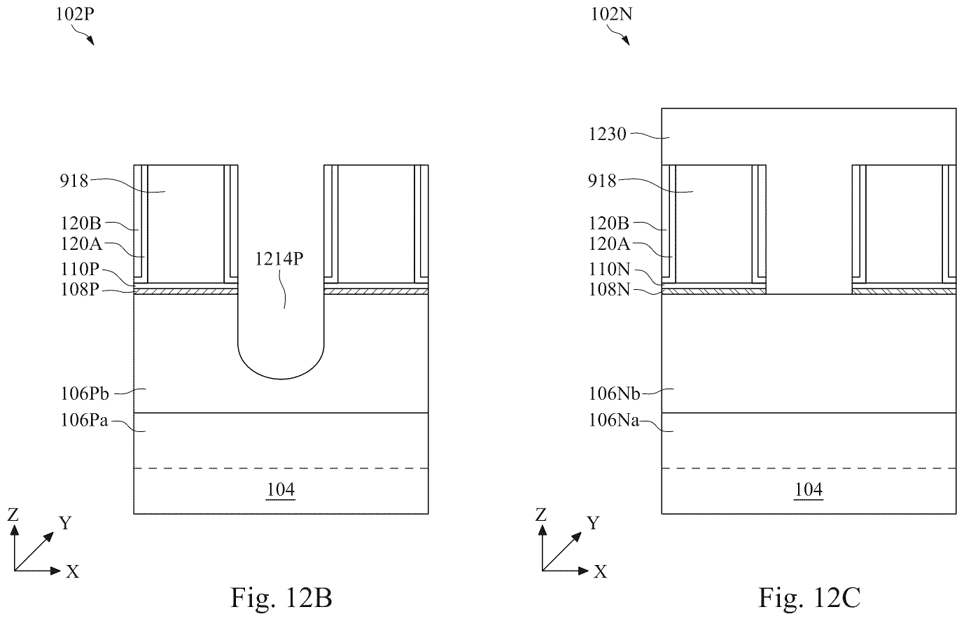

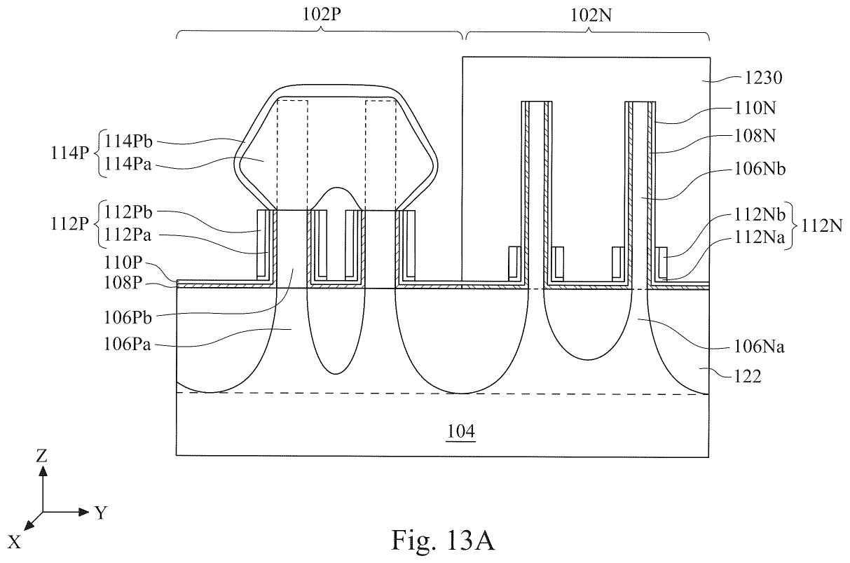

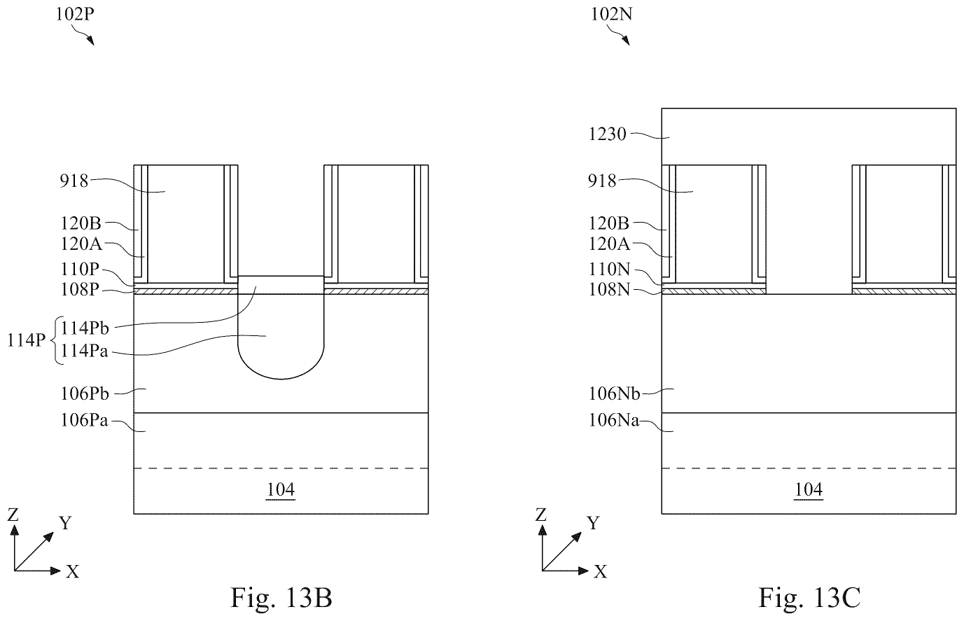

Referring to FIG. 2, in operation 240, S/D regions of the PFET are formed on the fin structures of the PFET. For example, as described with reference to FIGS. 12A-12C and 13A-13C, S/D region 114P is formed on fin structures 106Pb. In some embodiments, the formation of S/D regions 114P can include sequential operations of (i) forming a masking layer 1230 (e.g., SiN layer) on NFET 102N, as shown in FIGS. 12A and 12C (NFET 102N not visible in FIG. 12B), (ii) etching portions of fin structures 106Pb not covered by polysilicon structures 918 of PFET 102P to form S/D openings 1214P, as shown in FIGS. 12A and 12B, (iii) epitaxially growing S/D sub-regions 114Pa on fin structures 106Pb in S/D openings 1214P, as shown in FIGS. 13A and 13B, and (iv) epitaxially growing S/D sub-regions 114Pb on S/D sub-regions 114Pa, as shown in FIGS. 13A and 13B. The formation of S/D regions 114P can be followed by the removal of masking layer 1230 from NFET 102N.

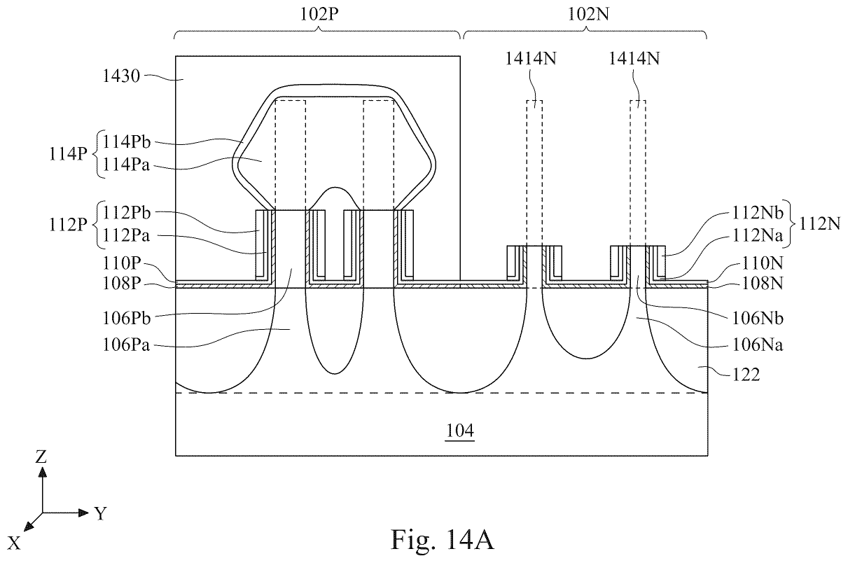

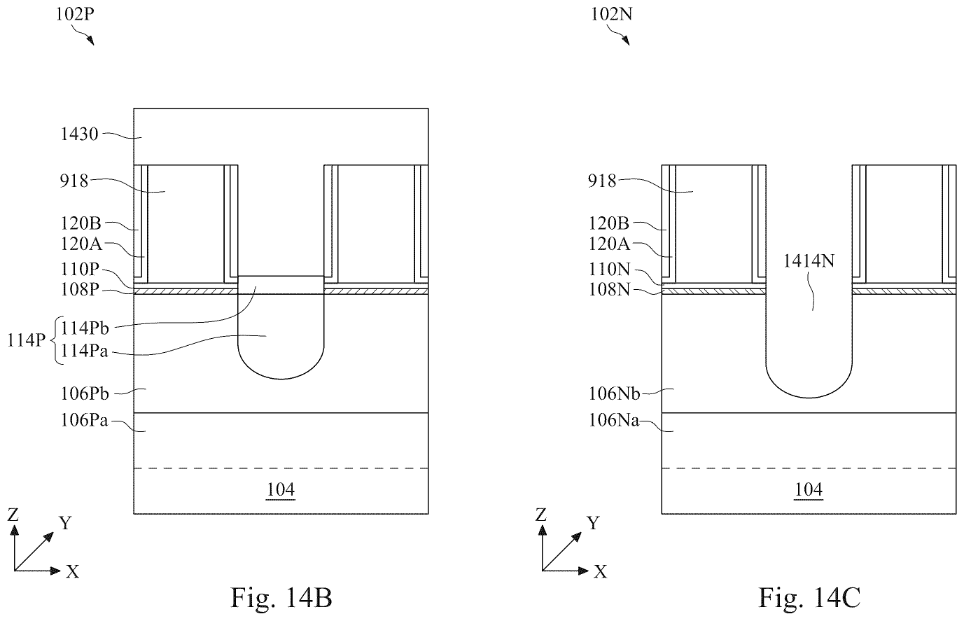

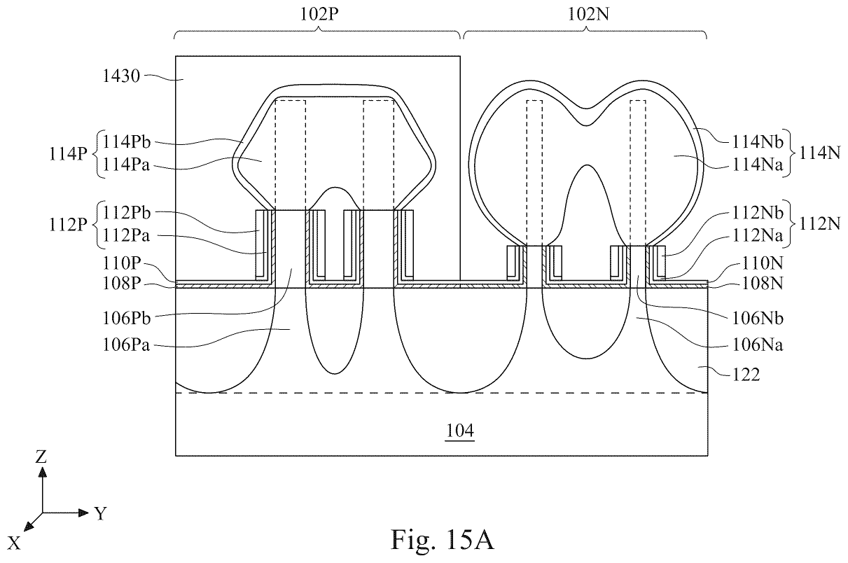

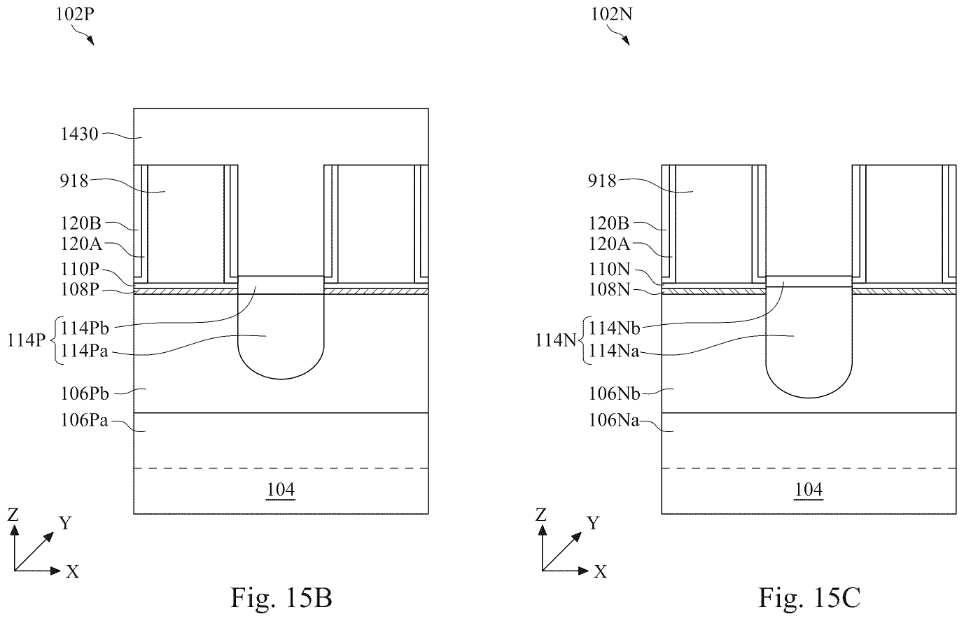

Referring to FIG. 2, in operation 245, S/D regions of the NFET are formed on the fin structures of the NFET. For example, as described with reference to FIGS. 14A-14C and 15A-15C, S/D region 114N is formed on fin structures 106Nb. In some embodiments, the formation of S/D regions 114N can include sequential operations of (i) forming a masking layer 1430 (e.g., SiN layer) on PFET 102P, as shown in FIGS. 14A and 14B (PFET 102P not visible in FIG. 12C), (ii) etching portions of fin structures 106Nb not covered by polysilicon structures 918 of NFET 102N to form S/D openings 1414N, as shown in FIGS. 14A and 14C, (iii) epitaxially growing S/D sub-regions 11NPa on fin structures 106Nb in S/D openings 1414N, as shown in FIGS. 15A and 15C, and (iv) epitaxially growing S/D sub-regions 114Nb on S/D sub-regions 11NPa, as shown in FIGS. 15A and 15B. The formation of S/D regions 114N can be followed by the removal of masking layer 1430 from PFET 102P. The formation of S/D region 114N can be followed by the formation of ESLs 124A and ILD layers 126A.

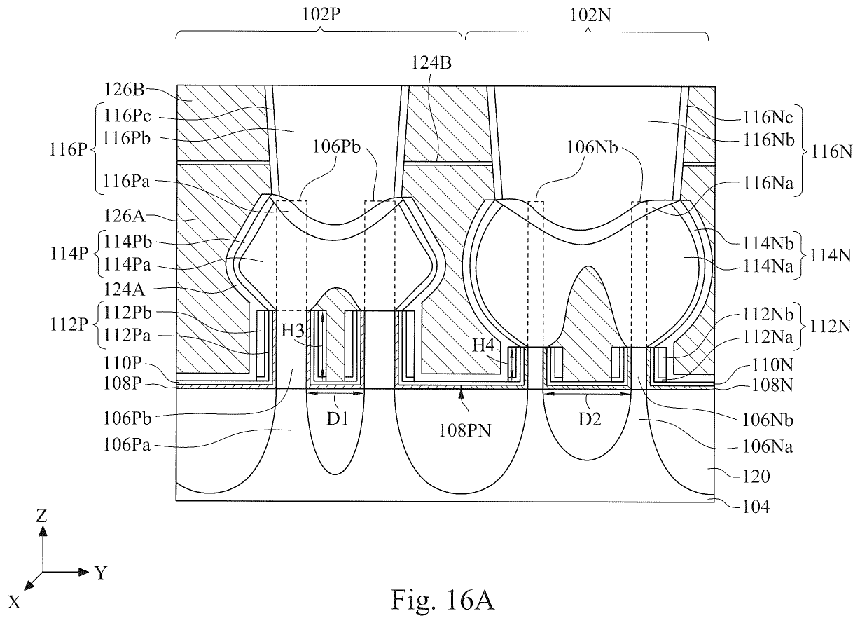

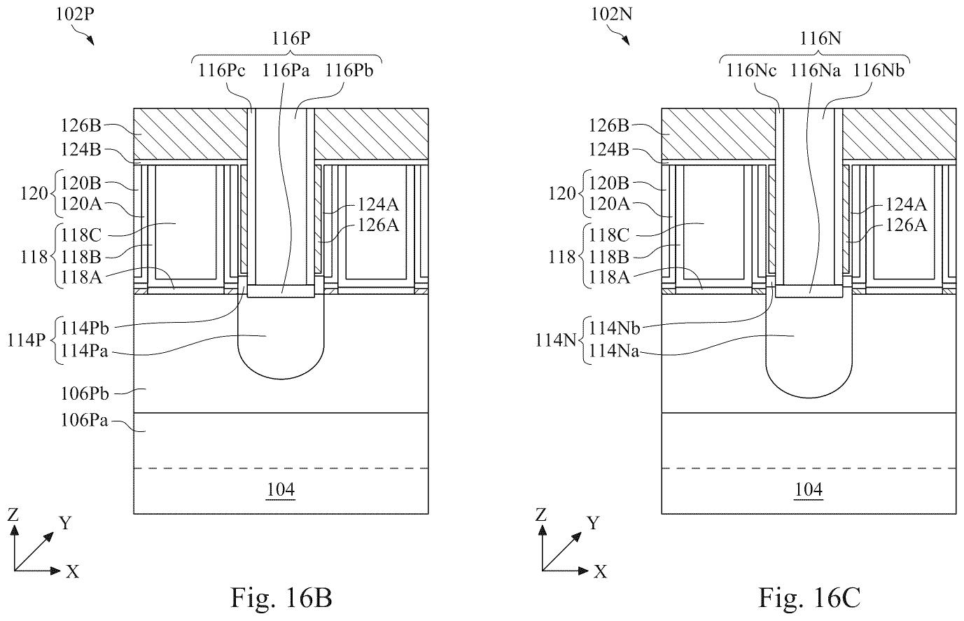

Referring to FIG. 2, in operation 250, the polysilicon structures are replaced with gate structures. For example, as shown in FIGS. 16B and 16C, polysilicon structures 918 are replaced with gate structures 118 (gate structures not visible in FIG. 16A) in a gate replacement process. In some embodiments, during the gate replacement process, portions of fin barrier layers 110P and 110N and fin capping layers 108P and 108N under polysilicon structures 918 can be removed along with polysilicon structures 918 prior to forming gate structures 118 on fin structures 106Pb and 106Nb, as shown in FIGS. 16B and 16C. In some embodiments, during the gate replacement process, portions of fin barrier layers 110P and 110N and fin capping layers 108P and 108N under polysilicon structures 918 may not be removed along with polysilicon structures 918 and gate structures 118 (without IL layer 118A) can be formed directly on fin barrier layers 110P and 110N to form the structures of FIGS. 1H and 1I.

In some embodiments, the formation of gate structures 118 can be followed by the formation of ESLs 124B and ILD layers 126B.

Referring to FIG. 2, in operation 255, contact structures are formed on the S/D regions of the PFET and NFET. For example, as shown in FIGS. 16A-16C, contact structures 116P and 116N are formed on S/D regions 114P and 114N through ESL 124A and 124B and ILD layers 126A and 126B.

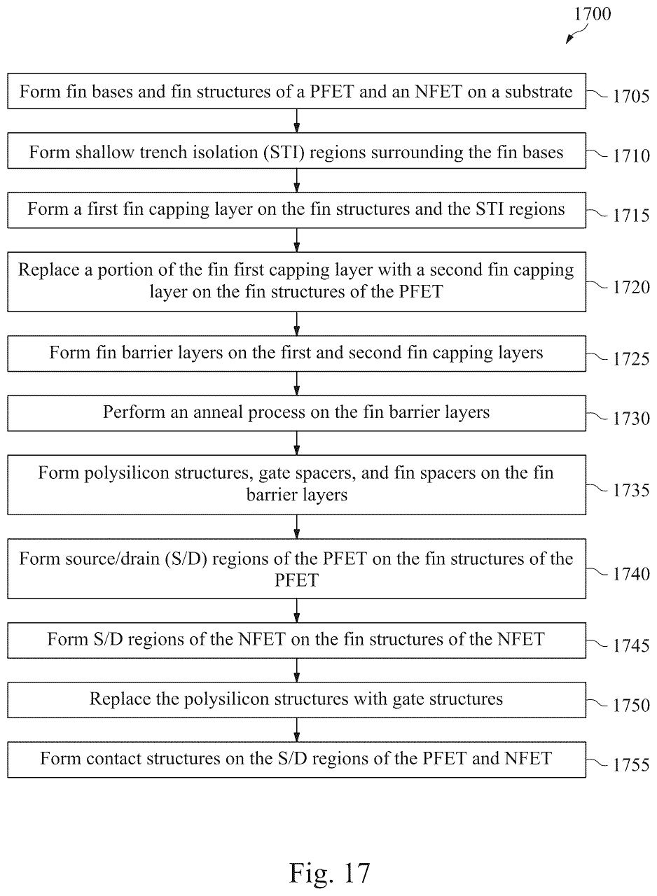

FIG. 17 is a flow diagram of an example method 1700 for fabricating semiconductor device 100 as described above with reference to FIGS. 1A and 1C-1E, according to some embodiments. For illustrative purposes, the operations illustrated in FIG. 17 will be described with reference to the example fabrication process for fabricating semiconductor device 100 as illustrated in FIGS. 18-25, 3B-16B, and 3C-16C. The cross-sectional views of semiconductor device 100 along lines B-B and C-C of FIGS. 1A and 1E during method 1700 is the similar to the cross-sectional views shown in FIGS. 3B-16B and 3C-16C for method 200, unless mentioned otherwise. FIGS. 17-25 are cross-sectional views of semiconductor device 100 along line A-A of FIG. 1A at various stages of fabrication, according to some embodiments. FIGS. 3B-16B are cross-sectional views of semiconductor device 100 along lines B-B of FIG. 1A and FIG. 1E at various stages of fabrication, according to some embodiments. FIGS. 3C-16C are cross-sectional views of semiconductor device 100 along lines C-C of FIGS. 1A and 1E at various stages of fabrication, according to some embodiments. Operations can be performed in a different order or not performed depending on specific applications. It should be noted that method 1700 may not produce a complete semiconductor device 100. Accordingly, it is understood that additional processes can be provided before, during, and after method 1700, and that some other processes may only be briefly described herein. The discussion of elements in FIGS. 1A-1E, 3A-16A, 3B-16B, 3C-16C, and 17-25 with the same annotations applies to each other, unless mentioned otherwise.

Referring to FIG. 17, operations 1705-1715 are the same as operations 205-215 of FIG. 2, respectively. After operation 1715, a structure with the cross-sectional views of FIGS. 3A-3C is formed. The subsequent operation 1720 of FIG. 17 is performed on the structures of FIGS. 3A-3C, as described below with reference to FIGS. 18, 19, 4B-6B, and 4C-6C.

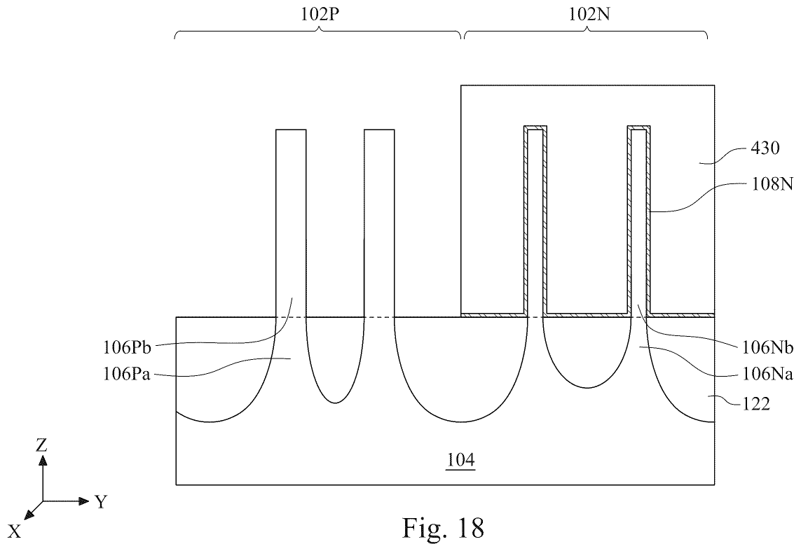

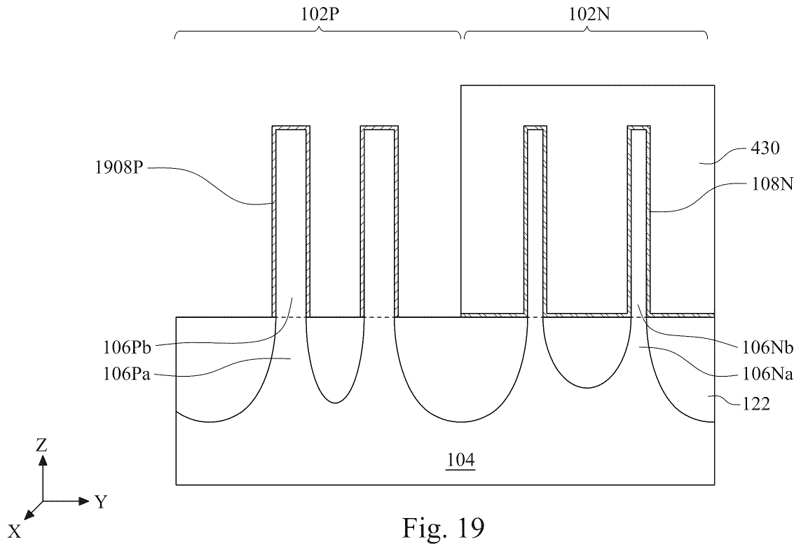

Referring to FIG. 17, in operation 1720, a portion of the first fin capping layer is replaced with a second fin capping layer on the fin structures of the PFET. For example, as described with reference to FIGS. 18, 19, 4A-4C, and 5A-5C, a portion of first fin capping layer 108N is replaced with a second fin capping layer 1908P having a SiGe layer on fin structures 106Pb. The replacement of the portion of first fin capping layer 108N can include sequential operations of (i) depositing a masking layer 430 (e.g., SiN layer) on first fin capping layer 108N, as shown in FIGS. 4A-4C, (ii) etching a portion of masking layer 430 to expose the portion of first fin capping layer 108N on fin structures 106Pb and on STI regions 122 of PFET 102, as shown in FIGS. 5A-5C, (iii) etching the exposed portion of first fin capping layer 108N to form the structure of FIG. 18, and (iv) epitaxially growing second fin capping layer 1908P having the SiGe layer with a Ge atom concentration of about 1 atomic % to about 20 atomic % on fin structures 106Pb, as shown in FIG. 19. The epitaxial growth process can be followed by the removal of masking layer 430 from fin capping layer 108N of NFET 102N.

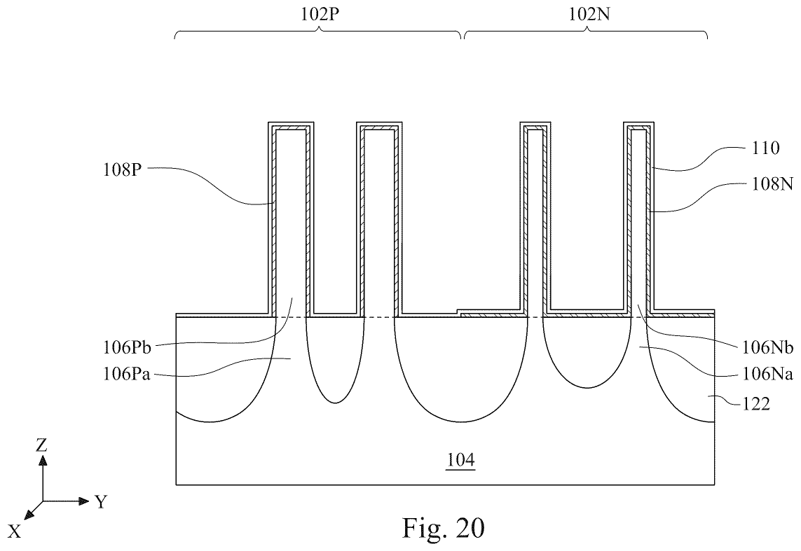

Referring to FIG. 17, in operation 1725, fin barrier layers are formed on the first and second fin capping layers. For example, as shown in FIGS. 20, 7B, and 7C, fin barrier layer 110N is formed on fin capping layer 108N and fin barrier layer 110P is formed on fin capping layer 1908P, which oxidizes to form fin capping layer 108P (shown in FIGS. 20 and 7B) having SiGeOₓ during the formation of fin barrier layers 110P and 110N. A portion of fin barrier layer 110P can be formed directly on STI regions 122 of PFET 102P (shown in FIG. 20) as fin capping layer 1908P is not epitaxially grown on STI regions 122 in operation 1720. The formation of fin barrier layers 110P and 110N can be the same as the process of forming fin barrier layers 110P and 110N in operation 225, described with reference to FIGS. 7A-7C.

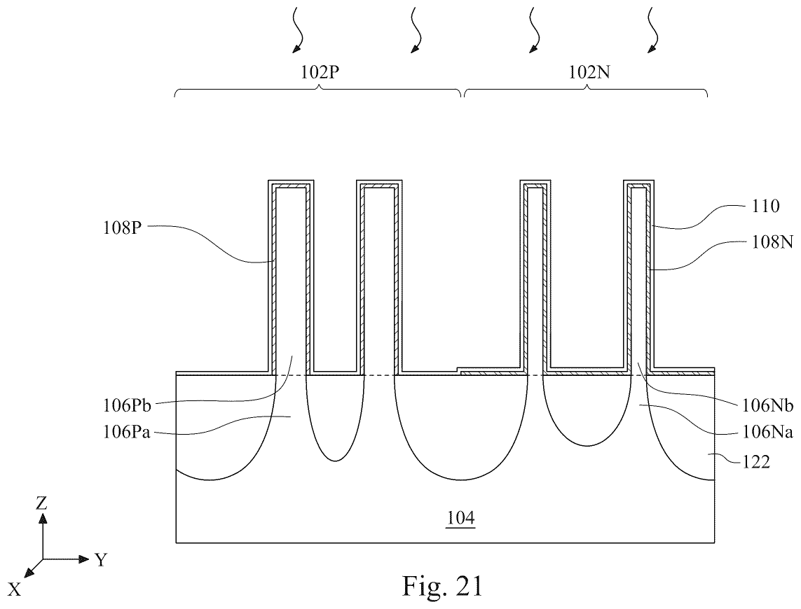

Referring to FIG. 17, in operation 1730, an anneal process is performed on the fin barrier layer. For example, as shown in FIG. 21, an anneal process is performed on fin barrier layers 110P and 110N in the same process described in operation 230.

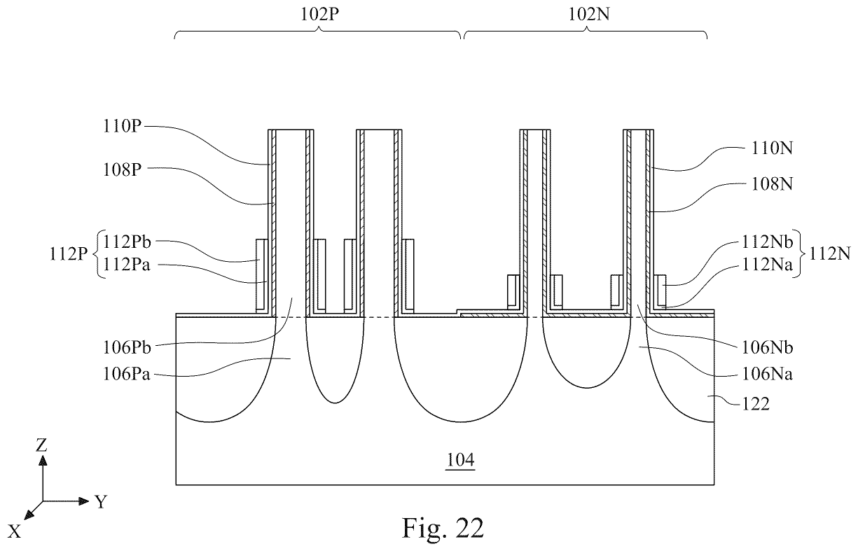

Referring to FIG. 17, in operation 1735, polysilicon structures, gate spacers, and fin spacers are formed on the fin barrier layer. For example, as shown in FIGS. 22, 11B, and 11C, polysilicon structures 918, gate spacers 120, and fin spacers 112P and 112N are formed on fin barrier layers 110P and 110N in the same processes described in operation 235.

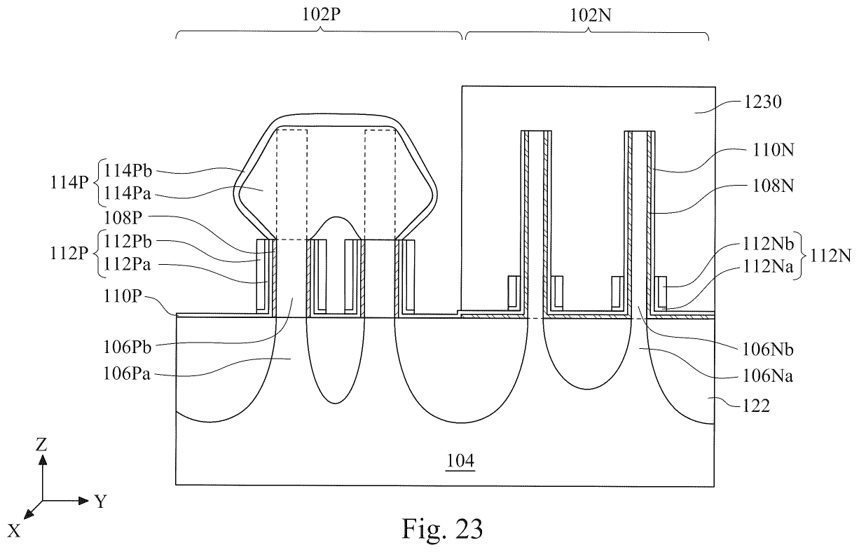

Referring to FIG. 17, in operation 1740, S/D regions of the PFET are formed on the fin structures of the PFET. For example, as shown in FIGS. 23 and 13B, S/D regions 114P are formed on fin structures 106Pb in the same processes described in operation 240.

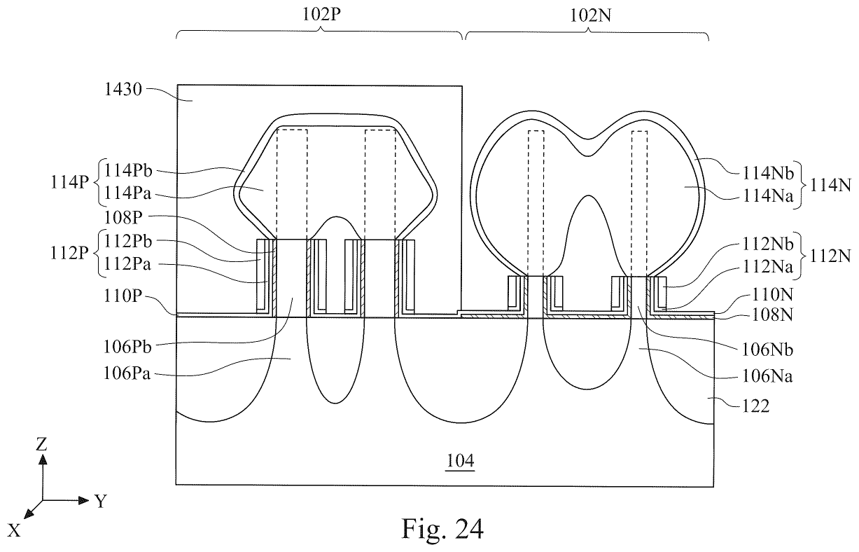

Referring to FIG. 17, in operation 1745, S/D regions of the NFET are formed on the fin structures of the NFET. For example, as shown in FIGS. 24 and 15C, S/D regions 114N are formed on fin structures 106Nb in the same processes described in operation 245.

Referring to FIG. 17, in operation 1750, the polysilicon structures are replaced with gate structures. For example, as shown in FIGS. 16B and 16C, polysilicon structures 918 are replaced with gate structures 118 in the same processes as in operation 250.

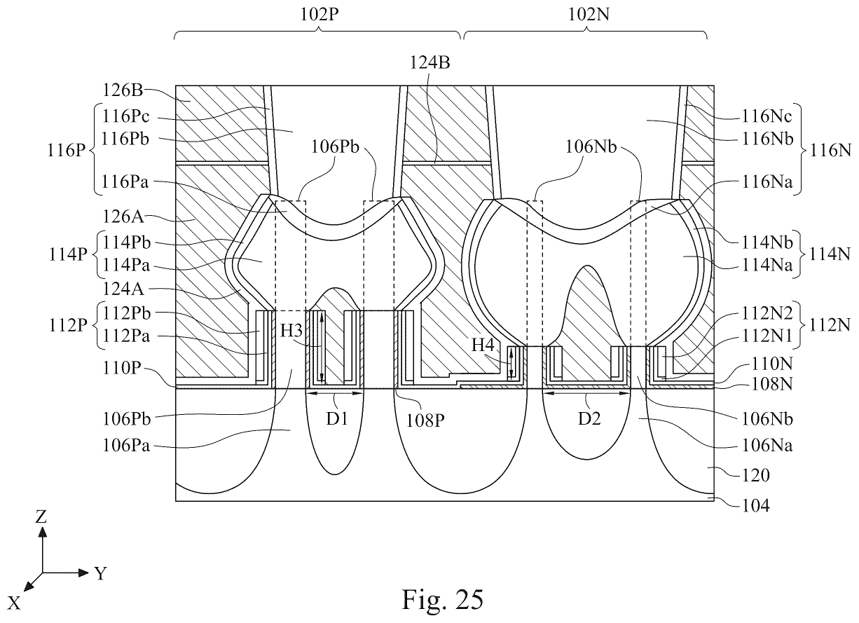

Referring to FIG. 17, in operation 1755, contact structures are formed on the S/D regions of the PFET and NFET. For example, as shown in FIGS. 25, 16B, and 16C, contact structures 116P and 116N are formed on S/D regions 114P and 114N in the same processes as in operation 255.

In some embodiments, semiconductor 100 with the cross-sectional view of FIG. 1F can be formed with method 200, except (i) in operation 215, first fin capping layer 108N (e.g., undoped Si layer) can be epitaxially grown on fin structures 106Pb and 106Nb, instead of depositing on fin structures 106Pb and 106Nb and on the top surfaces of STI regions 122, and (ii) in operation 225, fin barrier layers 110P and 110N can be formed by epitaxially grown Si layers on fin capping layers 608P and 108N followed by an anneal process on the Si layer at a temperature of about 600 °C to about 1100 °C in an oxygen ambient or in a steam and oxygen ambient, instead of depositing fin barrier layers 110P and 110N on fin capping layers 608P and 108N. As a result of using these epitaxial processes, fin capping layers 108P and 108N and fin barrier layers 110P and 110N are not formed on STI regions 122, as shown in FIG. 1F.

In some embodiments, semiconductor 100 with the cross-sectional view of FIG. 1F can be formed with method 1700, except, in operation 1725, fin barrier layers 110P and 110N can be formed by epitaxially grown Si layers on fin capping layers 1908P and 108N followed by an anneal process on the Si layer at a temperature of about 600 °C to about 1100 °C in an oxygen ambient or in a steam and oxygen ambient, instead of depositing fin barrier layers 110P and 110N on fin capping layers 1908P and 108N. As a result of using these epitaxial processes, fin capping layers 108P and 108N and fin barrier layers 110P and 110N are not formed on STI regions 122, as shown in FIG. 1F.

The present disclosure provides example semiconductor devices (e.g., semiconductor device 100) with p-type PFETs and NFETs having fin capping layers for improving device performance. The present disclosure also provides examples methods (e.g., methods 200 and 1700) of fabricating these semiconductor devices. In some embodiments, a PFET (e.g., PFET 102P) can include p-type fin structures (e.g., fin structures 106Pb), p-type fin capping layers (e.g., fin capping layers 108) disposed along sidewalls of the p-type fin structures, and fin barrier layers (e.g., fin barrier layers 110P) disposed on the p-type fin capping layers. In some embodiments, the fin barrier layers can prevent the diffusion of atoms to and from the p-type fin structures and improve surface quality of the p-type fin structures, and the p-type fin capping layers can improve the interface between the barrier layers and the p-type fin structures.

In some embodiments, the p-type fin structures can include a material (e.g., SiGe) with a lattice constant that is different from the material (e.g., SiO₂) of the fin barrier layers, which can induce strain on the p-type fin structures due to lattice mismatch between the materials of the p-type fin structures and the fin barrier layers. Such strain can induce crystal defects, such as dislocations and voids in the p-type fin structures, which can degrade the performance of the PFETs (e.g., increase device threshold voltage). The p-type fin capping layers can include a material (e.g., SiGeOₓ) that can reduce the strain between the p-type fin structures and the fin barrier layers, thus improving the device performance.

Similarly, in some embodiments, an NFET (e.g., NFET 102N) can include n-type fin structures (e.g., fin structures 106Nb), n-type fin capping layers (e.g., fin capping layers 108N) disposed along sidewalls of the n-type fin structures, and fin barrier layers (e.g., fin barrier layers 110N) disposed on the n-type fin capping layers. In some embodiments, the n-type fin structures and the n-type fin capping layers can include the same semiconductor material (e.g., Si) and the fin barrier layers can include the same material (e.g., SiO₂) as the barrier layers of the PFET.

In some embodiments, a method includes epitaxially growing a first fin structure having a first material on a substrate, epitaxially growing a second fin structure having a second material on the substrate, forming a first fin capping layer on the first and second fin structures, converting a portion of the first fin capping layer into a second fin capping layer on the first fin structure, forming first and second fin barrier layers on the first and second fin capping layers, respectively, forming first and second polysilicon structures on the first and second fin barrier layers, respectively, epitaxially growing a first S/D region on the first fin structure, epitaxially growing a second S/D region on the second fin structure, and replacing the first and second polysilicon structures with first and second gate structures.

In some embodiments, a method includes forming first and second fin structures on a substrate, depositing a first fin capping layer having a first material on the first and second fin structures, replacing a portion of the first fin capping layer with a second fin capping layer having a second material different from the first material, forming first and second oxide layers on the first and second fin capping layers, respectively, forming first and second polysilicon structures on the first and second oxide layers, respectively, forming first and second S/D regions on the first and second fin structures, respectively, and replacing the first and second polysilicon structures with first and second gate structures.

In some embodiments, a semiconductor device includes a substrate, a first fin structure having a first material disposed on the substrate, a second fin structure having a second material different from the first material disposed on the substrate, a first fin capping layer having the first material disposed on sidewalls of the first fin structure, a second fin capping layer having a third material different from the first and second materials disposed on sidewalls of the second fin structure, first and second oxide layers disposed on the first and second fin capping layers, respectively, first and second S/D regions disposed on the first and second fin structures, respectively, and first and second gate structures disposed on the first and second fin structures, respectively.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
epitaxially growing a first fin structure having a first material on a substrate;
epitaxially growing a second fin structure having a second material on the substrate;
forming a first fin capping layer on the first and second fin structures;
converting a portion of the first fin capping layer into a second fin capping layer on the first fin structure; and
forming first and second fin barrier layers on the first and second fin capping layers, respectively.

2. The method of claim 1, wherein forming the first fin capping layer comprises depositing an undoped silicon layer on the first and second fin structures.

3. The method of claim 1, wherein forming the first fin capping layer comprises epitaxially growing a silicon layer on the first and second fin structures.

4. The method of claim 1, wherein converting the portion of the first fin capping layer into the second fin capping layer comprises performing a doping process on the portion of the first fin capping layer.

5. The method of claim 1, wherein converting the portion of the first fin capping layer into the second fin capping layer comprises exposing the portion of the first fin capping layer to a germanium precursor gas.

6. The method of claim 1, wherein converting the portion of the first fin capping layer into the second fin capping layer comprises converting a silicon layer into a silicon germanium layer.

7. The method of claim 1, wherein forming the first and second fin barrier layers comprises depositing an oxide layer on the first and second fin capping layers.

8. The method of claim 1, wherein forming the first and second fin barrier layers comprises:
depositing a semiconductor layer on the first and second fin capping layers; and
performing an anneal process on the semiconductor layer in an oxygen ambient.

9. The method of claim 1, further comprising performing an anneal process on the first and second fin barrier layers in a hydrogen ambient.

10. The method of claim 1, further comprising forming first and second fin spacers on first and second fin barrier layers, respectively.

11. A method, comprising:
forming first and second fin structures on a substrate;
depositing a first fin capping layer having a first material on the first and second fin structures;
replacing a portion of the first fin capping layer with a second fin capping layer having a second material different from the first material; and
forming first and second oxide layers on the first and second fin capping layers, respectively.

12. The method of claim 11, wherein depositing the first fin capping layer comprises depositing an undoped silicon layer on the first and second fin structures.

13. The method of claim 11, wherein replacing the portion of the first fin capping layer with the second fin capping layer comprises replacing a silicon layer with a silicon germanium layer.

14. The method of claim 11, wherein replacing the portion of the first fin capping layer with the second fin capping layer comprises:
etching the portion of the first fin capping layer to expose the second fin structure; and
epitaxially growing the second fin capping layer on the second fin structure.

15. The method of claim 11, further comprising performing an anneal process on the first and second oxide layers in a hydrogen ambient.

16. The method of claim 11, further comprising forming first and second fin spacers on first and second oxide layers, respectively.

17. A semiconductor device, comprising:
a substrate;
a first fin structure having a first material disposed on the substrate;
a second fin structure having a second material different from the first material disposed on the substrate;
a first fin capping layer having the first material disposed on sidewalls of the first fin structure;
a second fin capping layer having a third material different from the first and second materials disposed on sidewalls of the second fin structure; and
first and second oxide layers disposed on the first and second fin capping layers, respectively.

18. The semiconductor device of claim 17, wherein the third material is an oxide of the second material.

19. The semiconductor device of claim 17, wherein the third material comprises silicon germanium oxide.

20. The semiconductor device of claim 17, further comprising first and second fin spacers disposed on the first and second oxide layers.
